(19) United States
(12) Patent Application Publication
(10) Pub. No.: US 2024/0210502 A1
(43) Pub. Date: Jun. 27, 2024

(54) SYSTEMS AND METHODS FOR MAGNETIC RESONANCE IMAGING

(71) Applicant: SHANGHAI UNITED IMAGING HEALTHCARE CO., LTD., Shanghai (CN)

(72) Inventors: Zheng ZHANG, Shanghai (CN); Junyu CHEN, Shanghai (CN); Tuoyu CAO, Shanghai (CN)

(73) Assignee: SHANGHAI UNITED IMAGING HEALTHCARE CO., LTD., Shanghai (CN)

(21) Appl. No.: 18/398,094

(22) Filed: Dec. 27, 2023

(30) Foreign Application Priority Data
Dec. 27, 2022 (CN) 202223510266.X

(51) Int. Cl. G01R 33/34; G01R 33/36; G01R 33/54

(52) U.S. Cl. CPC G01R 33/34084; G01R 33/3692; G01R 33/546

(57) ABSTRACT

A method and system for magnetic resonance imaging are provided. The method may include obtaining relevant information of a subject; determining, based on the relevant information of the subject, an area of the subject to be scanned; determining, based on the area of the subject to be scanned, one or more bed positions of a couch for one or more scans of the subject; controlling movement of an RF receiving coil for each of the one or more scans of the one or more of bed positions of the subject; and causing a magnetic resonance (MR) scanner to perform the one or more scans of the one or more of bed positions of the subject.

### CROSS-REFERENCE TO RELATED APPLICATIONS

This application claims priority to Chinese Patent Application No. 202223510266.X, filed on Dec. 27, 2022, the entire contents of which are incorporated herein by reference.

### TECHNICAL FIELD

The present disclosure relates to the field of medical imaging technology, in particular, to methods and systems for magnetic resonance imaging.

### BACKGROUND

The magnetic resonance imaging (MRI) performed on human body requires a surface receiving coil to receive signals, and the surface receiving coil with the high-performance can also improve the image acquisition efficiency. However, the weight of the surface receiving coil covering the body of a patient has caused compression on the patient, and the patient may not be able to tolerate the compression of the surface receiving coil on the chest and abdomen and may give up the examination. In addition, the compression of the surface receiving coil causes deformation of the patient's body surface, which is not suitable for imaging of the magnetic resonance (MR) system in radiotherapy simulation positioning. Moreover, the fixation of the surface receiving coil also requires additional operation by an operator. The improper fixation methods of the surface receiving coil may affect the image quality of the MR system and reduce the inspection efficiency of the MR system. When conducting a full body examination on the patient, multiple surface receiving coils need to be covered from the patient's head to the middle thigh, complicating the examination workflow and reducing patient tolerance.

Therefore, it is desirable to provide a system and a method for imaging to improve the efficiency of the process of scanning and improve the comfortableness of the patient.

### SUMMARY

One aspect of embodiments of the present disclosure may provide a system. The system may include a magnetic resonance (MR) scanner; a radio frequency (RF) receiving coil configured to receive an MR signal during each of scans of a plurality of bed positions of a subject; and a transmission component configured to move the RF receiving coil for each of the scans of the plurality of bed positions of the subject; wherein the transmission component is configured to apply one or more forces in at least two directions to the RF receiving coil to control the RF receiving coil to move during each of the scans.

In some embodiments, the transmission component may be configured to: after a couch moves for a scan of a first bed position among the plurality of bed positions, move the RF receiving coil to a target position; after the MR scanner performs the scan of the first bed position when the RF receiving coil is at the target position, move the RF receiving coil from the target position to an intermediate position; and after the couch moves for a scan of a second bed position among the plurality of bed positions, move the RF receiving coil from the intermediate position to the target position.

In some embodiments, the moving the RF receiving coil from the target position to the intermediate position may include raising the RF receiving coil from the target position to the intermediate position.

In some embodiments, the moving the RF receiving coil from the intermediate position to the target position may include dropping the RF receiving coil from the intermediate position to the target position.

In some embodiments, the transmission component may be further configured to keep the RF receiving coil at the target position during the scan of the first bed position or the second bed position.

In some embodiments, the transmission component may include a first pulley connected with the RF receiving coil and a first cable, a first end of the first cable is connected with the MR scanner, and a second end of the first cable extends to outside of the MR scanner after bypassing the first pulley.

In some embodiments, the transmission component may include a second cable, a first end of the second cable being connected with the RF receiving coil and a second end of the second cable extending to outside of the MR scanner.

In some embodiments, the transmission component may include a first pulley connected with the RF receiving coil; a second pulley provided on the MR scanner; a first cable, a first end of the first cable being connected with the first pulley, and a second end of the first cable extending to outside of the MR scanner after bypassing the second pulley.

In some embodiments, the transmission component may include a second cable, a first end of the second cable being connected with the RF receiving coil and a second end of the second cable extending to outside of the MR scanner.

In some embodiments, the transmission component may include a third cable, a first end of the third cable being connected with the RF receiving coil and a second end of the third cable being connected with the MR scanner after bypassing the first pulley.

In some embodiments, the transmission component may include one or more pulleys and one or more cables.

In some embodiments, the transmission component further may include a driving element connected with the one or more cables, the driving element being configured to provide one or more drawings forces to the one or more cables.

In some embodiments, the transmission component further may include a direction change assembly configured to change a direction of at least one of the one or more cables, the direction change assembly being provided on one end of the MR scanner.

In some embodiments, the transmission component may include one or more gas bags, one of sides of each of the one or more gas bags being connected with the MR scanner, and one of the sides of each of the one or more gas bags being connected with the RF receiving coil.

Another aspect of embodiments of the present disclosure may provide a system. The system may include at least one storage medium including a set of instructions; at least one processor in communication with the at least one storage medium, wherein when executing the set of instructions, the at least one processor is directed to cause the system to perform operations including: after a couch moves for a scan of a first bed position among a plurality of bed positions, moving the RF receiving coil to a target position; after a magnetic resonance (MR) scanner performs the scan of the first bed position when the RF receiving coil is at the target position, moving the RF receiving coil from the target position to an intermediate position; and after the couch moves for a scan of a second bed position among the plurality of bed positions, moving the RF receiving coil from the intermediate position to the target position.

In some embodiments, the moving the RF receiving coil from the target position to the intermediate position may include raising the RF receiving coil from the target position to the intermediate position.

In some embodiments, the moving the RF receiving coil from the intermediate position to the target position may include dropping the RF receiving coil from the intermediate position to the target position.

In some embodiments, the method may further include keeping the RF receiving coil at the target position during the scan of the first bed position or the second bed position.

Another aspect of embodiments of the present disclosure may provide a system. The system may include obtaining relevant information of a subject; determining, based on the relevant information of the subject, an area of the subject to be scanned; determining, based on the area of the subject to be scanned, one or more bed positions of a couch for one or more scans of the subject; controlling movement of an RF receiving coil for each of the one or more scans of the one or more of bed positions of the subject; and causing a magnetic resonance (MR) scanner to perform the one or more scans of the one or more of bed positions of the subject.

In some embodiments, the controlling movement of an RF receiving coil for each of the one or more scans of the one or more of bed positions of the subject may include after a couch moves for a scan of a first bed position among a plurality of bed positions, moving the RF receiving coil to a target position; after a magnetic resonance (MR) scanner performs the scan of the first bed position when the RF receiving coil is at the target position, moving the RF receiving coil from the target position to an intermediate position; and after the couch moves for a scan of a second bed position among the plurality of bed positions, moving the RF receiving coil from the intermediate position to the target position.

### BRIEF DESCRIPTION OF THE DRAWINGS

The present disclosure is further illustrated in terms of exemplary embodiments, and these exemplary embodiments are described in detail with reference to the drawings. These embodiments are not restrictive. In these embodiments, the same number indicates the same structure, wherein:

FIG. 1 is a schematic diagram illustrating an exemplary application scenario of a system for magnetic resonance imaging according to some embodiments of the present disclosure;

FIG. 2 is a schematic diagram illustrating an exemplary medical device according to some embodiments of the present disclosure;

FIG. 3A is a schematic diagram illustrating an exemplary system for magnetic resonance imaging according to some embodiments of the present disclosure;

FIG. 3B is a schematic diagram illustrating another exemplary system for magnetic resonance imaging according to some embodiments of the present disclosure;

FIG. 3C is a schematic diagram illustrating another exemplary system for magnetic resonance imaging according to some embodiments of the present disclosure;

FIG. 3D is a schematic diagram illustrating another exemplary system for magnetic resonance imaging according to some embodiments of the present disclosure;

FIG. 3E is a schematic diagram illustrating another exemplary system for magnetic resonance imaging according to some embodiments of the present disclosure;

FIG. 4 is a schematic diagram illustrating an exemplary gas bag of a system for magnetic resonance imaging when the gas bag is expanding according to some embodiments of the present disclosure;

FIG. 5 is a schematic diagram illustrating an exemplary gas bag of a system for magnetic resonance imaging when the gas bag is contracting according to some embodiments of the present disclosure;

FIG. 6 is a schematic diagram illustrating another exemplary system for magnetic resonance imaging according to some embodiments of the present disclosure;

FIG. 7 is a flowchart illustrating an exemplary process of a magnetic resonance (MR) scanning according to some embodiments of the present disclosure;

FIG. 8 is a block diagram illustrating an exemplary system for magnetic resonance imaging according to some embodiments of the present disclosure; and

FIG. 9 is a schematic diagram illustrating an exemplary control device of a system for magnetic resonance imaging according to some embodiments of the present disclosure; and

FIG. 10 is a flowchart illustrating an exemplary process of scanning performed by a medical device according to some embodiments of the present disclosure; and

FIG. 11 is QA results for geometric distortion after the gradient linearity calibration.

### DETAILED DESCRIPTION

In order to illustrate the technical solutions related to the embodiments of the present disclosure, a brief introduction of the drawings referred to in the description of the embodiments is provided below. Obviously, drawings described below are only some examples or embodiments of the present disclosure. Those having ordinary skills in the art, without further creative efforts, may apply the present disclosure to other similar scenarios according to these drawings. Unless stated otherwise or obvious from the context, the same reference numeral in the drawings refers to the same structure and operation.

It will be understood that the terms “system,” “device,” “unit,” and/or “module” used herein are one method to distinguish different components, elements, parts, sections, or assemblies of different levels in ascending order. However, the terms may be displaced by other expressions if they may achieve the same purpose.

As shown in the present disclosure and claims, unless the context clearly indicates exceptions, the words “a,” “an,” “one,” and/or “the” do not specifically refer to the singular, but may also include the plural. The terms “including” and “comprising” only suggest that the steps and elements that have been clearly identified are included, and these steps and elements do not constitute an exclusive list, and the method or device may also include other steps or elements.

The flowcharts used in the present disclosure may illustrate operations executed by the system according to embodiments in the present disclosure. It should be understood that a previous operation or a subsequent operation of the flowcharts may not be accurately implemented in order. Conversely, various operations may be performed in inverted order, or simultaneously. Moreover, other operations may be added to the flowcharts, and one or more operations may be removed from the flowcharts.

In the process of scanning a patient based on the magnetic resonance imaging (MRI), it is necessary to provide scanning coils on the surface of the patient to increase the efficiency of image acquisition. However, there are generally a large count of scanning coils that require manual fixation or release by an operator, which is cumbersome and inefficient, thus reducing the tolerance of the patient. Further, the scanning coils may compress the patient, reducing the comfort.

To address the above issues, some embodiments of the present disclosure provide a system. The system includes a magnetic resonance (MR) scanner; a radio frequency (RF) receiving coil configured to receive an MR signal during each of scans for a plurality of bed positions of a subject; and a transmission component configured to move the RF receiving coil for each of the scans of the plurality of bed positions of the subject. The RF receiving coil is moved based on the transmission component to achieve the fixation and release of the RF receiving coil on the surface of the patient, without the need for manual operation by the operator, making the movement of the RF receiving coil convenient and improving the work efficiency. At the same time, by carrying the RF receiving coil based on the transmission component, the RF receiving coil may not cause compression on the patient, improving the comfort.

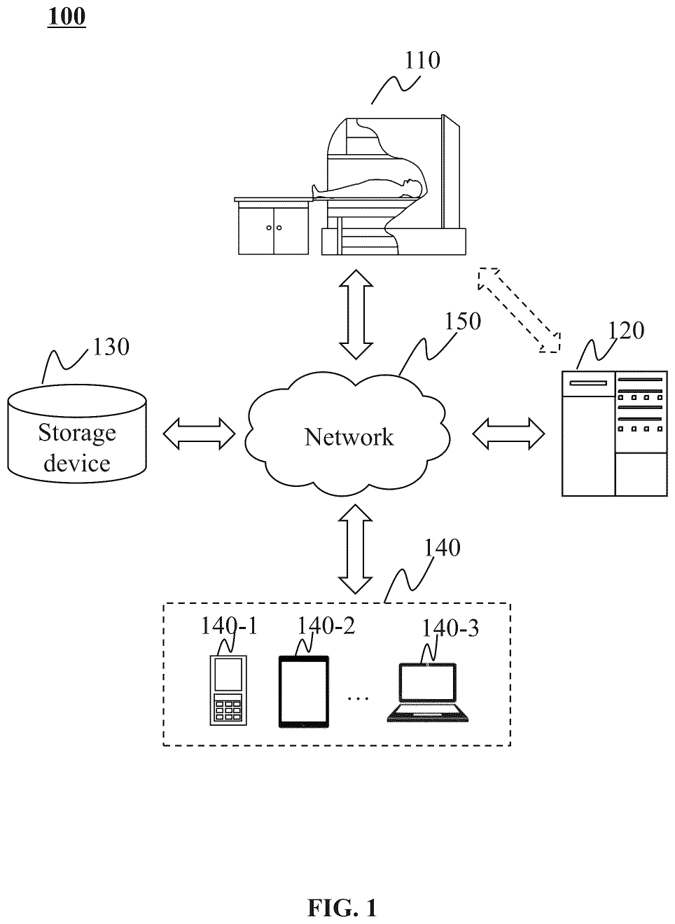

FIG. 1 is a schematic diagram illustrating an exemplary application scenario of a system for magnetic resonance imaging according to some embodiments of the present disclosure.

As shown in FIG. 1, in some embodiments, the system 100 may include a medical device 110, a processing device 120, a storage device 130, a terminal 140, and a network 150.

The medical device 110 may be a single-modality scanner. For example, the medical device 110 may include a magnetic resonance imaging (MRI) device. In some embodiments, the medical device 110 may be a multi-modality medical device. For example, the medical device 110 may include a computed tomography (CT)-MRI scanner, a positron emission tomography (PET)-MRI scanner, an MR-guided radiotherapy device (e.g., MRI Linac (linear accelerator)), or the like, or any combination thereof. The medical device 110 provided above is for illustrative purposes only and is not limited in scope.

Taking an MRI device as an example for illustration, the MRI device may include a magnet, a gradient coil, an RF coil, a pulse sequence device, etc. The magnet may generate a static main magnetic field during the scanning of MRI. The gradient coil may generate magnetic field gradients for a main magnetic field in different directions (or axes). The RF coil may send an RF pulse to a subject undergoing examination and/or receive an MR signal from the subject. The pulse sequence device may determine a pulse sequence.

The processing device 120 may process data and/or information obtained from components in other devices or system, based on the data, information and/or processing results, perform the imaging methods for shown in some embodiments of the present disclosure to complete one or more of the functions described in some embodiments of the present disclosure. In some embodiments, the processing device 120 may include one or more processing engines (e.g., a single-chip processing engine or a multi-chip processing engine). Merely by way of example, the processing device 120 may include a central processing unit (CPU).

In some embodiments, the processing device 120 may include one or more sub-processing devices (e.g., a single-core processing device or multi-core processing device). Merely for example, the processing device 120 may include a central processing unit (CPU), a specialized integrated circuit (ASIC), a specialized instruction processor (ASIP), a graphics processor (GPU), a physical processor (PPU), a digital signal processor (DSP), a field programmable gate array (FPGA), a programmable logic circuit (PLD), a controller, a microcontroller unit, a reduced instruction set computer (RISC), a microprocessor, or any combination thereof.

The storage device 130 may store data or information generated by other devices. In some embodiments, the storage device 130 may store data and/or information collected by the medical device 110, such as a multimodal image. In some embodiments, the storage device 130 may store data and/or information processed by the processing device 120, such as the registration relationship between images. The storage device 130 may include one or more storage components, each of which may be an independent device or a part of other devices. The storage device 130 may be local or implemented through the cloud.

The terminal 140 may facilitate communication between the user and other components (e.g., the medical device 110, the processing device 120, the storage device 130) of the system 100. The terminal 140 may include a user interface. The user interface may facilitate interaction between the user and the other components (e.g., the medical device 110, the processing device 120, the storage device 130).

For example, the user may input a control instruction through the user interface, and the control instruction may be used to control an operation of the medical device 110. The control instruction may enable the medical device 110 to complete a designated operation, such as scanning and imaging of a specific body portion of a patient. As another example, the user may input a request instruction through the terminal 140 and the request instruction may instruct the processing device 120 to control a movement of the RF coil as shown in some embodiments of the present disclosure.

As still another example, the terminal 140 may receive information and/or data from other components (e.g., the medical device 110, the processing device 120, the storage device 130) of the system 100 and display the information and/or data on the user interface. For example, the terminal 140 may receive multiple images from the medical device 110 or the processing device 120 and display the multiple images via the user interface.

In some embodiments, the terminal 140 may be one or any combination of other devices with display screen, input and/or output functions, such as mobile devices 140-1, tablet computers 140-2, laptop computers 140-3, desktop computers, or the like.

The network 150 may connect various components of the system and/or connect the system with external resource parts. The network 150 may enable communication between various components and with other parts outside the system, promoting the exchange of data and/or information. In some embodiments, one or more components in the system 100 (e.g., the medical device 110, the processing device 120, the storage device 130, the terminal 140) may send data and/or information to other components through the network 150. In some embodiments, the network 150 may be any one or more of wired or wireless networks.

It should be noted that the above description is provided for illustrative purposes only and is not intended to limit the scope of this specification. For ordinary technical personnel in this field, various changes and modifications can be made under the guidance of the content of the present disclosure. The features, structures, methods, and other features of the exemplary embodiments described in the present disclosure can be combined in various ways to obtain additional and/or alternative exemplary embodiments. For example, the processing device 120 may be based on cloud computing platforms, such as public clouds, private clouds, communities, and hybrid clouds. However, these changes and modifications will not deviate from the scope of the present disclosure.

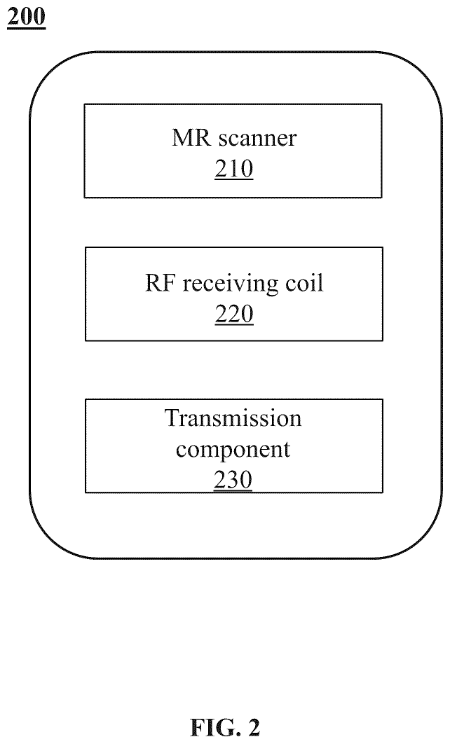

FIG. 2 is a schematic diagram illustrating an exemplary medical device according to some embodiments of the present disclosure. As shown in FIG. 2, the medical device 200 may include a magnetic resonance (MR) scanner 210, a radio frequency (RF) receiving coil 220, and a transmission component 230.

The MR scanner 210 may be configured to perform an MR scan of a subject and generate MR signals of the subject. The MR scanner 210 may include a magnet, a gradient coil, an RF coil, and a pulse sequence device. The magnet may generate a static main magnetic field during a MRI scan. The magnet may be various types, such as a permanent magnet, a superconductive magnet, a resistance electromagnet, etc.. The gradient coil may generate magnetic field gradients for a main magnetic field on different directions (or axes). The different directions may be determined based on different types of the gradient coils. For example, a Z-direction coil may be designed based on a circular (Maxwell) coil, while an X-direction coil and a Y-direction coil may be designed based on a Golay coil, etc. The X-direction may also be referred to as a read out (RO) direction (or a frequency encoding direction), the Y-direction may also be referred to as a phase encoding (PE) direction, and the Z-direction may also be referred to as a chip encoding direction. The RF coil may send a RF pulse to a subject undergoing examination and/or receive a MR signal from the subject. The pulse sequence device may determine a pulse sequence.

In some embodiments, the RF coil may include a RF transmitting coil and/or a RF receiving coil 220. The RF transmitting coil may send an RF pulse signal, which may excite atomic nuclei in the human body and form a resonance with the Lamar frequency. The RF receiving coil 220 may be configured to receive the MR signals generated from the subject under the magnetic field. In the embodiments of the present disclosure, the RF coil may merely include the RF transmitting coil, and the RF receiving coil 220 may be installed as an external device in the MR scanner 210. The RF receiving coil 220 may include a coil shaped liking a bird cage, a transverse electromagnetic coil, a saddle coil, etc. In some embodiments, the RF receiving coil 220 may be a surface coil. The surface coil may be placed close to or on a surface of a subject, with high imaging signal-to-noise ratio, strong anti-interference ability, and good stability.

The MR scanner 210 may further include a couch. The couch may move in a scanning region of the MR scanner 210. The couch may be configured to place and/or move a subject for scanning.

The transmission component 230 may be configured to move the RF receiving coil 220 for a scan of a subject. In some embodiments, scans for a plurality of bed positions may be performed by the MR scanner 210. Different portions of the subject may be scanned according to the scans of the plurality of bed positions. Each portion of the subject may be scanned during the scan of one of the plurality of bed positions. For each of the scans of the plurality of bed position positions, a couch placing the subject may be moved to the bed position in the scanning region of the MR scanner 210. The transmission component 230 may be configured to move the RF receiving coil 220 to a target position for a scan of one of the plurality of bed positions before each of the scans of the plurality of bed positions of the subject. A portion of the subject may be scanned after the RF receiving coil 220 is located at the target position. The target position may be located at the surface of the portion of the subject or above and close the portion of the subject, such that the RF receiving coil 220 may receive the MR signals generated from the portion of the subject. It should be noted that in the present disclosure, the meaning of “close the portion of the subject” refers to: no more than 5 cm away from the subject. The RF receiving coil 200 located at the target position may cover the portion of the subject.

For example, two adjacent bed positions may include a first bed position and a second bed position after the first bed position. After the couch is moved to the first bed position, the RF receiving coil 220 may be moved to the target position corresponding to the first bed position by the transmission component 230, and the RF receiving coil 220 may be located on or near a first portion of the subject. The MR scanner 210 may perform a scan of the first bed position. After the MR scanner 210 performs the scan of the first bed position when the RF receiving coil 220 is at the target position corresponding to the first bed position, the RF receiving coil 220 may be moved by the transmission component 230 from the target position corresponding to the first bed position to an intermediate position corresponding to the first bed position. The couch may be moved to the second bed position. The RF receiving coil 220 may be moved from the intermediate position to a target position corresponding to the second bed position by the transmission component 230. During the scan of the first bed position and the scan of the second bed position, the RF receiving coil 220 may be kept at the target position corresponding to the first bed position and the target position corresponding to the second bed position.

In some embodiments, the target position corresponding to the first bed position may be the same as the target position corresponding to the second bed position.

The transmission component 230 may be configured to provide at least two movement freedoms for the RF receiving coil.

In some embodiments, the transmission component 230 may apply one or more drawing forces in at least two directions to the RF receiving coil 220 to control the RF receiving coil 220 to move.

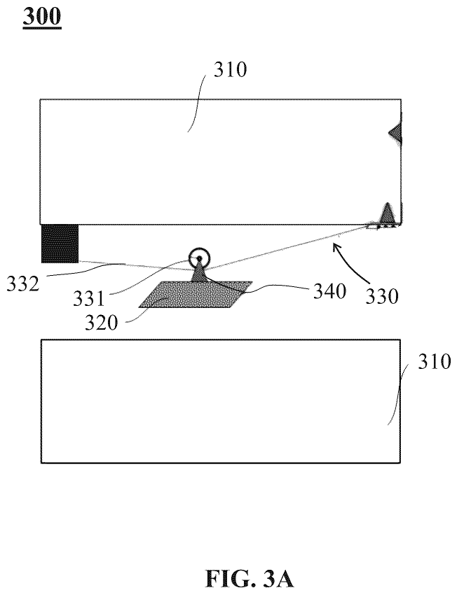

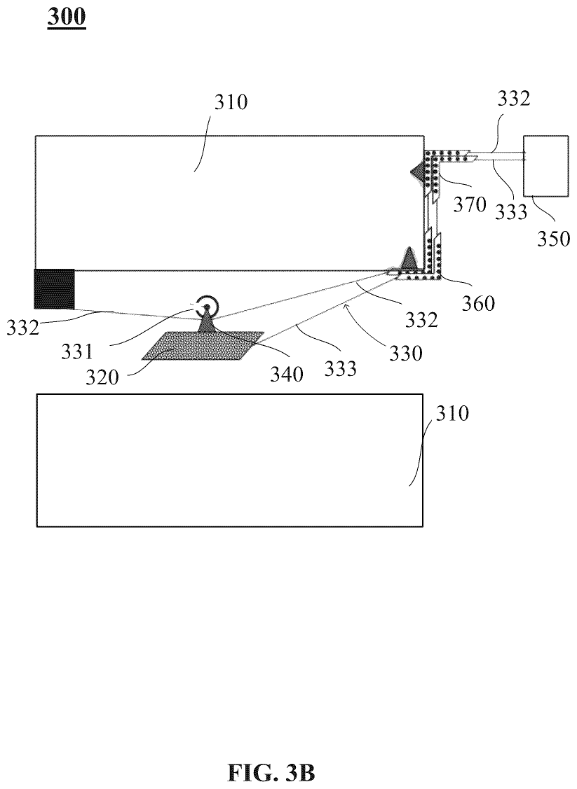

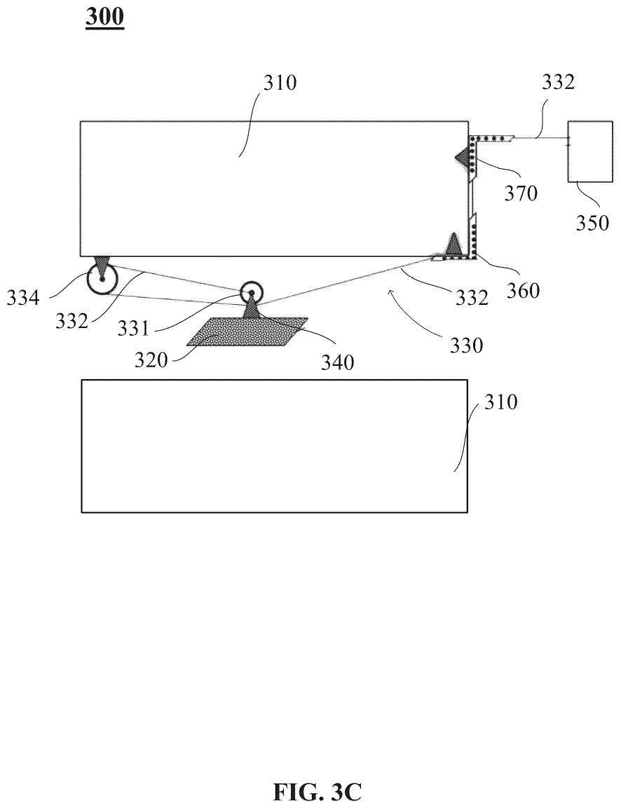

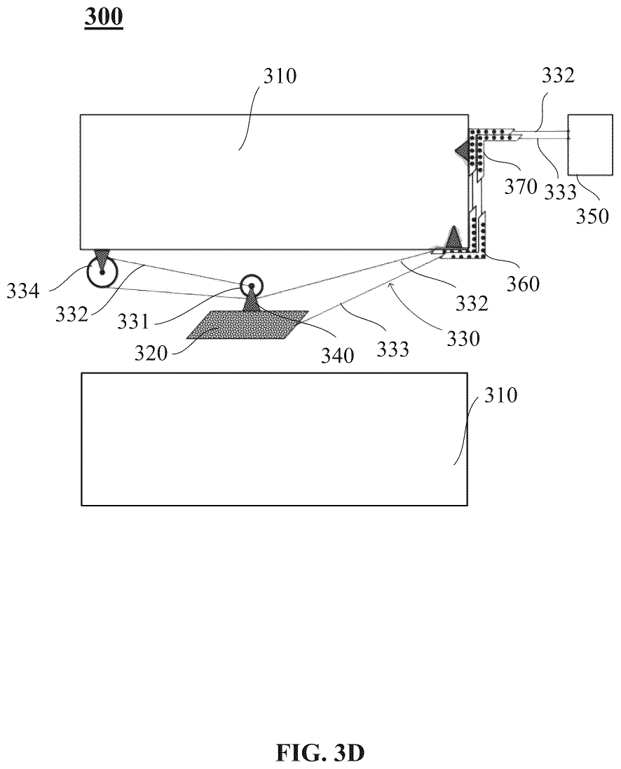

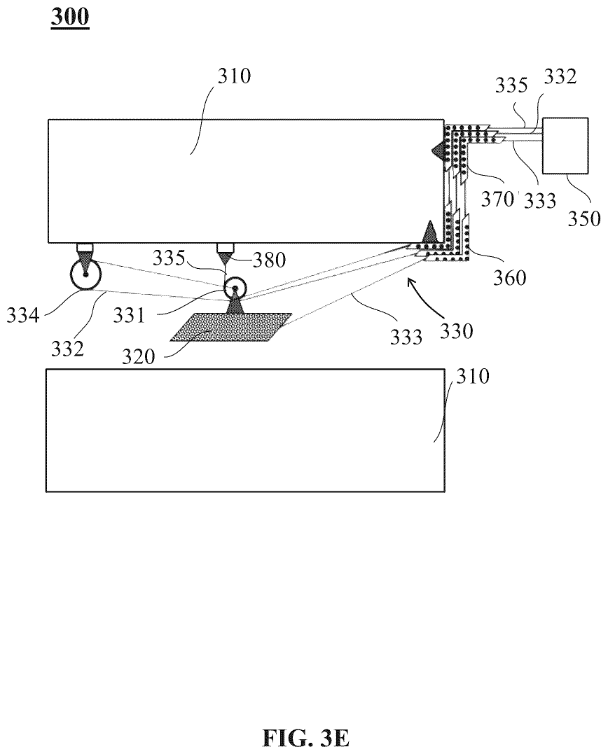

In some embodiments, the transmission component (e.g., the transmission component 330 in FIG. 3A) may include a first pulley (e.g., the first pulley 331 in FIG. 3A) connected with the RF receiving coil (e.g., the RF receiving coil 320 in FIG. 3A) and a first cable (e.g., the first cable 332 in FIG. 3A). A first end of the first cable may be connected with the MR scanner (e.g., the MR scanner 310 in FIG. 3A), and a second end of the first cable (e.g., the first cable 332 in FIG. 3A) may extend to outside of the MR scanner (e.g., the MR scanner 310 in FIG. 3A) after bypassing the first pulley (e.g., the first pulley 331 in FIG. 3A). In some embodiments, the transmission component (e.g., the transmission component 330 in FIG. 3B) may include a first pulley (e.g., the first pulley 331 in FIG. 3B), a first cable (e.g., the first cable 332 in FIG. 3B) and a second cable (e.g., the second cable 333 in FIG. 3B). A first end of the second cable (e.g., the second cable 333 in FIG. 3B) may be connected with the RF receiving coil (e.g., the RF receiving coil 320 in FIG. 3B) and a second end of the second cable (e.g., the second cable 333 in FIG. 3B) may extend to outside of the MR scanner (e.g., the MR scanner 310 in FIG. 3B). In some embodiments, the transmission component (e.g., the transmission component 330 in FIG. 3C) may include a first pulley (e.g., the first pulley 331 in FIG. 3C), a second pulley (e.g., the second pulley 334 in FIG. 3C) provided on the MR scanner (e.g., the MR scanner 310 in FIG. 3C), and a first cable (e.g., the first cable 332 in FIG. 3C). A first end of the first cable (e.g., the first cable 332 in FIG. 3C) may be connected with the first pulley (e.g., the first pulley 331 in FIG. 3C), and a second end of the first cable (e.g., the first cable 332 in FIG. 3C) may extend to outside of the MR scanner (e.g., the MR scanner 310 in FIG. 3C) after bypassing the second pulley. In some embodiments, the transmission component (e.g., the transmission component 330 in FIG. 3D) may include a first pulley (e.g., the first pulley 331 in FIG. 3D), a second pulley (e.g., the second pulley 334 in FIG. 3D) provided on the MR scanner (e.g., the MR scanner 310 in FIG. 3D), a first cable (e.g., the first cable 332 in FIG. 3D), and a second cable (e.g., the second cable 333 in FIG. 3D). A first end of the second cable (e.g., the second cable 333 in FIG. 3D) may be connected with the RF receiving coil (e.g., the RF receiving coil 320 in FIG. 3D) and a second end of the second cable (e.g., the second cable 333 in FIG. 3D) may extend to outside of the MR scanner (e.g., the MR scanner 310 in FIG. 3D). In some embodiments, the transmission component (e.g., the transmission component 330 in FIG. 3E) may include a first pulley (e.g., the first pulley 331 in FIG. 3E), a second pulley (e.g., the second pulley 334 in FIG. 3E) provided on the MR scanner (e.g., the MR scanner 310 in FIG. 3E), a first cable (e.g., the first cable 332 in FIG. 3E), a second cable (e.g., the second cable 333 in FIG. 3E), and a third cable (e.g., the third cable 335 in FIG. 3E). A first end of the third cable (e.g., the third cable 335 in FIG. 3E) may be connected with the RF receiving coil (e.g., the RF receiving coil 320 in FIG. 3E) and a second end of the third cable (e.g., the third cable 335 in FIG. 3E) may be connected with the MR scanner (e.g., the MR scanner 310 in FIG. 3E) after bypassing the first pulley (e.g., the first pulley 331 in FIG. 3E). By changing a direction of a cable through a pulley, and through a coordination between the cable and the pulley, the tension applied to the RF receiving coil (e.g., the RF receiving coil 320 in FIG. 3E) may be changed, thus to drive the RF receiving coil (e.g., the RF receiving coil 320 in FIG. 3E) to move.

In some embodiments, the transmission component 230 may be configured to apply deformation forces in at least two directions to the RF receiving coil 220 to control the RF receiving coil 220 to move during each of scans.

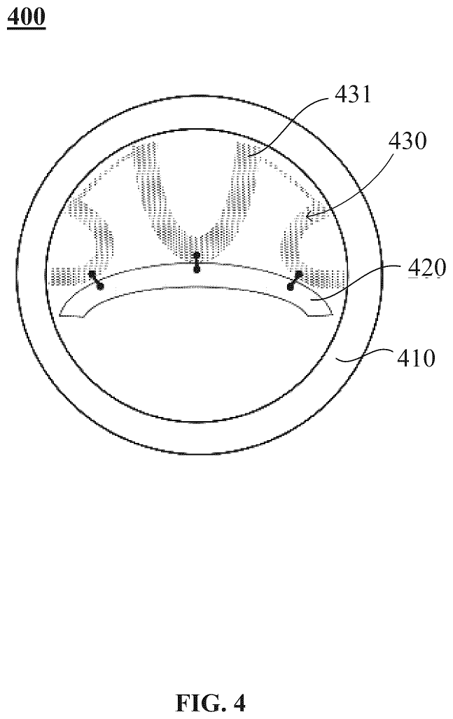

In some embodiments, the transmission component (e.g., the transmission component 430 in FIGS. 4-6) may include one or more gas bags (e.g., the gas bag 431 in FIGS. 4-6). One of sides of each of the one or more gas bags may be connected with the MR scanner (e.g., the MR scanner 410 in FIGS. 4-6), and one of the sides of each of the one or more gas bags (e.g., the MR scanner 410 in FIGS. 4-6) may be connected with the RF receiving coil (e.g., the RF receiving coil 420 in FIGS. 4-6). By controlling a expansion or contraction of the one or more gas bags (e.g., the MR scanner 410 in FIGS. 4-6), and applying a deformation force on at least two directions to the RF receiving coil (e.g., the RF receiving coil 420 in FIGS. 4-6), the RF receiving coil (e.g., the RF receiving coil 420 in FIGS. 4-6) may be driven to move, thus adjusting a position of RF receiving coil (e.g., the RF receiving coil 420 in FIGS. 4-6).

In some embodiments, the transmission component 230 may also include other structures that can apply a force on the RF receiving coil 220 to move the RF receiving coil 220, which may not be limited in the present disclosure. For example, the transmission component 230 may also include a plurality of cables. A first end of each of the plurality of cables may be connected with the RF receiving coil 220 and distributed around the RF receiving coil 220. A second end of each of the plurality of cables may be connection with a translation mechanism (e.g., a slider, a slide, etc.) installed in an internal cavity of the MR scanner 210. By moving the translation mechanism, the plurality of cables may be driven to move the RF receiving coil 220.

In some embodiments, the transmission component 230 may also include a mechanical arm and a moving mechanism. The moving mechanism may be located at the top of the internal cavity of the MR scanner 210. One end of the mechanical arm may be connected with the moving mechanism for transmission, allowing the mechanical arm to move with respect to the moving mechanism. For example, a slider guide rail may be used to cooperate between the mechanical arm and the moving mechanism. Another end of the mechanical arm may be connected with the RF receiving coil 220. In some embodiments, the moving mechanism may be provided along an extension direction of the internal cavity of the MR scanner 210, and the mechanical arm may move with respect to the moving mechanism to drive the RF receiving coil 220 to move horizontally, adjusting a horizontal position of the RF receiving coil 220 within the MR scanner 210.

In some embodiments, the mechanical arm may be equipped with a telescopic structure (e.g., a telescopic arm), which may adjust the length of the mechanical arm to drive the RF receiving coil 220 to move vertically and adjust the height position of the RF receiving coil 220 within the MR scanner 210.

In some embodiments, an end of the mechanical arm near the RF receiving coil 220 may be connected with the RF receiving coil 220 via two or more mechanical claws. The two or more mechanical claws may provide forces in at least two directions to the RF receiving coil 220 to control the expanding or bending of the RF receiving coil 220. In some embodiments, the two or more mechanical claws may be uniformly distributed around an axis of the mechanical arm, which means that the angle between any two adjacent mechanical claws is 360° divided by the total number of mechanical claws ,to apply more uniform force to the RF receiving coil 220. In some embodiments, each of the two or more mechanical claws may rotate around a connection point between the mechanical claw and the mechanical arm, allowing the two or more mechanical claws to close or open to control the RF receiving coil 220 to bend or expand.

In some embodiments, a movement of the mechanical arm on the moving mechanism, a telescopic motion of the mechanical arm, and the opening or closing of the two or more mechanical claws may be driven by separate motors, respectively.

In some embodiments, a tension or a deformation force applied by the transmission component to the RF receiving coil 220 on at least two directions may also drive the RF receiving coil 220 to unfold or bend, so that the RF receiving coil 220 may be close to or cover the surface of the subject. In some embodiments, the RF receiving coil 220 may have a memory function, and an initial state of the RF receiving coil 220 may be a folded state. Under the drawing forces along the pair of opposite directions mentioned above, the RF receiving coil 220 may expand from a folded state. After releasing the drawing forces along the pair of opposite directions, the RF receiving coil 220 may automatically return to the initial state (i.e., folded state).

The beneficial effects of the embodiments of the present disclosure may include, but may not be limited to: (1) moving the RF receiving coil based on the transmission component to achieve the fixation and loosening of the RF receiving coil on the body surface of the patient, without the need for manual operation by an operator, making the RF receiving coil easy to move and improving the work efficiency; (2) by supporting the RF receiving coil based on the transmission component, the accuracy for controlling the position of the RF receiving coil may be improved, and the RF receiving coil may also prevent compression on the patient, improving the comfort of the patient; (3) by driving the transmission component to adjust the position of the RF receiving coil, an automated operation may be achieved and the surgical efficiency may be improved; (4) during the multi-bed position scanning, the RF receiving coil may move simultaneously during the movement of a bed position, thereby improving the efficiency of the multi-bed position scanning. It should be noted that different embodiments may produce different beneficial effects, and in different embodiments, the possible beneficial effects may be any one or a combination of the above, or any other possible beneficial effects.

FIG. 3A is a schematic diagram illustrating an exemplary system for magnetic resonance imaging according to some embodiments of the present disclosure. As shown in FIG. 3A, some embodiments of the present disclosure provide a system (not shown). The system 300 may include an MR scanner 310, an RF receiving coil 320, and a transmission component 330. The MR scanner 310 may be used for MR imaging of a subject. In some embodiments, the subject may be scanned by the MR scanner 310 at a plurality of bed positions. The MR scanner 310 may sequentially scan different portions of the subject on a couch at the different bed positions, thereby achieving a multi-bed position scanning and improving the scanning efficiency.

During each scan of the plurality of bed positions of the subject by the MR scanner 310, the RF receiving coil 320 may receive an MR signal generated from the portion of the subject. The MR signal may be used for reconstructing an MR image of the portion of the subject. In each scan of the plurality of bed positions of the subject, the transmission component 330 may be used to move the RF receiving coil 320 for each of the scans of the plurality of bed positions of the subject. The transmission component 330 may support and fix the RF receiving coil 320 on the surface or near the surface of the subject during the scan of a bed position. The transmission component 330 may release and remove the RF receiving coil 320 from the surface of the subject after the scan is completed. By operating the RF receiving coil 320 based on the transmission component 330, the work efficiency may be improved, the compression caused by the RF receiving coil 320 on the patient may be avoided, thus improving the comfort of the patient.

In some embodiments, the RF receiving coil 320 may include a coil unit and a material for wrapping the coil unit. The material for wrapping the coil unit may be a flexible material, such as fabric, fur, or the like. Alternatively, the material for wrapping the coil unit may be polyethylene PE, polyvinyl chloride PVC, acrylonitrile butadiene styrene copolymer ABS, or the like, or a combination thereof.

In some embodiments, the plurality of bed positions of the subject scanned by the MR scanner 310 may sequentially include a first bed position, a second bed position, . . . , a n-th bed position. The couch placing the subject may be moved to the plurality of bed positions an order for scan.

In some embodiments, the transmission component 330 may be configured to move the RF receiving coil 320 to a target position when the couch is moved to the first bed position (i.e., after a couch moves into the MR scanner 310 for a scan of the first bed position among the plurality of bed positions). After the MR scanner 310 performs the scan of the first bed position when the RF receiving coil 320 is at the target position, the transmission component 330 may move the RF receiving coil 320 from the target position to an intermediate position. When the couch continues to move to the second bed position (i.e., after the couch moves from the first bed position to the second bed position among the plurality of bed positions), the transmission component 330 may move the RF receiving coil 320 from the intermediate position back to the target position. In some embodiments, when the RF receiving coil 320 is at the target position, the MR scanner 310 may cooperate with the RF receiving coil 320 to scan the patient. In some embodiments, repeating the above operations until the MR scanner 310 performs the scan of the n-th bed position, the multi-bed position scanning is completed by the MR scanner 310.

In some embodiments, during the movement of the couch to another bed position, the RF receiving coil 320 may move simultaneously from the target position to the intermediate position and/or from the intermediate position to the target position, thereby improving the efficiency of the multi-bed position scanning. For example, after the MR scanner 310 performs the scan of the first bed position, the RF receiving coil 320 may be moved from the target position to the intermediate position during a process of the couch moving from the first bed position to the second bed position. As another example, during the process of the couch moving from the first bed position to the second bed position, the RF receiving coil 320 may simultaneously move from the intermediate position to the target position.

In some embodiments, the target position refers to a fixed position of the RF receiving coil 320 when the MR scanner 310 performs a scan of a bed position.

In some embodiments, the target position may be a surface position of the subject. In some embodiments, since body shapes of patients on the plurality of bed positions may be different, and the corresponding surface positions of the patients may also be different, a plurality of target positions corresponding to the plurality bed position may be different. In some embodiments, in order to improve the scanning efficiency, the plurality of target positions corresponding to the plurality of bed positions may also be the same.

In some embodiments, the target position may be above the surface position of the subject. For example, a distance may be between the target position and the surface position of the subject. The distance may be in a range, such as 1 centimeter to 5 centimeters, or 1 centimeter to 2 centimeters, or the like. For patients with different shapes, there may be a gap between the target position and the body surface of a patient to avoid compression, which may avoid deformation of the body surface of the patient, affecting the scanning imaging effect, and reducing the tolerance of the patient. In some embodiments, the gap (i.e., the distance) between the target position and the body surface of the patient may not be too large to avoid a significant impact on the scanning and imaging.

In some embodiments, the target position may be determined based on historical data about the shapes of historical subjects. For example, the target position may be determined based on the historical data about the maximum thickness of the historical subjects. The thickness of a subject may be a length of the subject along the direction perpendicular to a horizontal plane.

In some embodiments, the intermediate position refers to a position of the RF receiving coil 320 when the MR scanner 310 pauses or stops scanning. In some embodiments, the intermediate position may be any position (e.g., a position outside the MR scanner 310, a position inside the MR scanner 310, etc.), as long as the position may not affect the movement of the couch.

In some embodiments, in order to reduce the movement distance of the RF receiving coil 320 and improve the scanning efficiency, the intermediate position may be located vertically above the target position. A height difference between the intermediate position and the target position may ensure that when the RF receiving coil 320 is at the intermediate position, the RF receiving coil 320 does not affect the movement of the couch or the subject on the couch.

The operation of moving the RF receiving coil 320 from the target position to the intermediate position may include raising the RF receiving coil 320 from the target position to the intermediate position. The operation of moving the RF receiving coil 320 from the intermediate position to the target position may include lowering the RF receiving coil 320 from the intermediate position to the target position.

In some embodiments, the transmission component 330 may further be configured to keep the RF receiving coil 320 at the target position during the scanning process of the MR scanner 310 (e.g., during the scan of the first bed position or the second bed position), so that the RF receiving coil 320 may cooperate with the MR scanner 310 to scan the patient and imaging.

In some embodiments, the transmission component 330 may be configured to provide at least two movement freedoms for the RF receiving coil 320. Thus, the transmission component 330 may control the movement of the RF receiving coil 320 with at least two freedoms.

In some embodiments, the transmission component 330 may be configured control the expansion and bending of the RF receiving coil 320. When the transmission component 330 controls the RF receiving coil 320 to move to the target position, the RF receiving coil 320 is in an unfolded state to facilitate the RF receiving coil 320 to cover the body surface of the patient closely. When the transmission component 330 controls the RF receiving coil 320 to move to the intermediate position, the RF receiving coil 320 is in a folded state, reducing the spatial volume of the RF receiving coil 320 and avoiding interference with the movement of the couch caused by the RF receiving coil 320.

In some embodiments, the transmission component 330 may be configured to provide the at least two movement freedoms for the RF receiving coil 320 by applying drawing forces on at least two directions to RF receiving coil 320. By applying the drawing forces on the at least two directions, the movement of the RF receiving coil 320 may be controlled.

In some embodiments, the at least two directions mentioned above may be a pair of opposite directions, and the RF receiving coil 320 may be controlled to move along a straight line along the two directions by drawing the RF receiving coil 320 along the two opposite directions. It should be noted that the RF receiving coil 320 may also move in other directions, such as the vertical direction, while moving along the two opposite directions mentioned above. In some embodiments, the pair of opposite directions may be perpendicular to a vertical direction, and the RF receiving coil 320 may move vertically based on a cooperation of the gravity of the RF receiving coil 320 and the drawing forces along the pair of opposite directions.

In some embodiments, the transmission component 330 may include one or more pulleys and one or more cables. By changing the direction of the one or more cables based on the one or more pulleys, different forces may be applied on the RF receiving coil 320 based on a cooperation between the one or more cables and the one or more pulleys to drive the RF receiving coil 320 to move.

As shown in FIG. 3A, the transmission component 330 may include a first pulley 331 connected with the RF receiving coil 320, and a first cable 332. A first end of the first cable 332 may be connected with the MR scanner 310, and a second end of the first cable 332 may extend to the outside of the MR scanner 310 after bypassing the first pulley 331. Through the second end of the first cable 332, the length of the first cable 332 in the internal cavity of MR scanner 310 can be controlled. Since the first end of the first cable 332 is fixed, the tension of the first cable 332 in the internal cavity of MR scanner 310 may be adjusted. Combined with the gravity of the first pulley 331 and the gravity of the RF receiving coil 320, a vertical movement of the RF receiving coil 320 in a vertical direction may be controlled, thereby controlling the height position of the RF receiving coil 320 within the MR scanner 310. For example, when the first cable 332 is relaxed, under the action of the gravity of the first cable 332, the gravity of the first pulley 331, and the gravity of the RF receiving coil 320, the first cable 332 may droop and bend downwards, and the RF receiving coil 320 may move vertically downwards. When the first cable 332 is tightened, the degree of downward bending of the first cable 332 may decrease, and the first pulley 331 and the RF receiving coil 320 may move vertically upwards until the first cable 332 is tightened to a situation that the first end is close to horizontal with the first pulley 331. In some embodiments, by cooperating with the movement of one of the plurality of bed positions, it is possible to achieve a horizontal movement of the RF receiving coil 320 as shown in FIG. 3A, thereby indirectly achieving a horizontal movement of the RF receiving coil 320.

In some embodiments, the transmission component 330 may also include a driving element (not shown), which may be connected to the second end of the first cable 332 to provide traction for the first cable 332. When the driving element provides the traction for the first cable 332, the first cable 332 may be tightened. When the first cable 332 is released, the driving element stops providing the traction, but the first cable 332 may not be locked.

In some embodiments, the first pulley 331 may be connected with the RF receiving coil 320 via a connecting part 340. By providing the connection part 340, interference with the rotation of the first pulley 331 caused by the RF receiving coil 320 may be avoided, allowing the first pulley 331 to slide along the first cable 332, thereby driving the RF receiving coil 320 to move.

Due to the inability to accurately control the horizontal movement (e.g., moving from a left side to a right side as shown in FIG. 3A) of the RF receiving coil 320 because of the arrangement of the first cable 332 and the first pulley 331, the accuracy of the installation and the fixation of the RF receiving coil 320 may be reduced, thereby affecting the efficiency of scanning. To accurately control the horizontal movement of the RF receiving coil 320, in some embodiments, a second cable (e.g., the second cable 333 in FIG. 3B) connected with the RF receiving coil 320 may be provided to directly draw the RF receiving coil 320 horizontally via the second cable. Alternatively, by changing a transmission relationship between the first cable 332 and the RF receiving coil 320, the first cable 332 may perform horizontal traction on the RF receiving coil 320. For example, by providing a second pulley, the first end of the first cable 332 may be connected with the first pulley 331, and the second end of the first cable 332 may extend outside of the MR scanner 310 after bypassing the first pulley 331.

FIG. 3B is a schematic diagram illustrating another exemplary system for magnetic resonance imaging according to some embodiments of the present disclosure. As shown in FIG. 3B, a difference between the system 300 shown in FIG. 3B and the system 300 shown in FIG. 3A is that the system 300 shown in FIG. 3B further includes a second cable 333. A first end of the second cable 333 may be connected with the RF receiving coil 320, and a second end of the second cable 333 may extend outside of the MR scanner 310. By controlling the second end of the second cable 333, the second cable 333 may directly apply force on the RF receiving coil 320 and the first pulley 331, thereby controlling the first pulley 331 to slide on the first cable 332, thereby controlling the horizontal movement of the RF receiving coil 320, and controlling a depth position of the RF receiving coil 320 within the MR scanner 310.

In some embodiments, the transmission component 330 may also include a driving element 350 connected with one or more cables. The driving element 350 may be configured to provide one or more drawings forces to the one or more cables. It should be noted that the driving element 350 may simultaneously provide different drawing forces for the one or more cables. For example, the driving element 350 may include one or more driving sources, each of the one or more driving sources may be connected with a cable, and each driving source may provide a drawing force to the corresponding cable. When a cable requires a drawing force, the corresponding driving source may work to provide the drawing force. When the cable is loosened or driven, the corresponding driving source may stop working, but the corresponding cable may not be locked.

In some embodiments, the MR scanner 310 may have a service end (a left end shown in FIGS. 3A-3E) and a maintenance end (a right end shown in FIGS. 3A-3E), and a bed position may enter the MR scanner 310 from the service end. In some embodiments, the driving element 350 may be arranged at the maintenance end on the right end of the MR scanner 310 to avoid affecting the convenience of the bed position entering the MR scanner 310.

In some embodiments, the transmission component 330 may also include a direction change assembly. The direction change assembly may be configured to change a direction of at least one of the one or more cables, in order to achieve control of the RF receiving coil 320 by controlling the one or more cables. In some embodiments, a free end of the cable (e.g., the second end of the first cable 332, the second end of the second cable 333, etc.) may be extended outside of the MR scanner 310 via the direction change assembly.

In some embodiments, the direction change assembly may be provided on one end near the driving element 350 of the MR scanner 310 (e.g., the right end of the MR scanner 310 as shown in FIGS. 3A-3E), and the one or more cables may be connected with the driving element 350 via the direction change assembly. The arrangement of the direction change assembly may make an arrangement position of the driving element 350 more flexible, while also allowing for a more flexible design of the cable routing to avoid cable entanglement and knots.

In some embodiments, the one or more cables in the direction change assembly may be independent and may not interfere with each other to avoid the adverse effects on the control of the RF receiving coil 320. In some embodiments, a count of the direction change assembly may be the same as a count of the one or more cables, with each direction change assembly corresponding to a cable to ensure that the one or more cables do not interfere with each other.

In some embodiments, the direction change assembly may include a first direction change assembly 360 and a second direction change assembly 370. The first direction change assembly 360 and the second direction change assembly 370 may be configured to change a direction of at least one of the one or more cables, causing the at least one cable to move in different directions.

In some embodiments, the transmission component 330 may also include a control device. The control device may be connected with the driving element 350 by a signal. The control device may control the driving element 350 to control a drawing speed or a loosening speed of each cable, thereby providing more accurate control of the position of the RF receiving coil 320 and reducing the possibility of the RF receiving coil 320 offset.

FIG. 3C is a schematic diagram illustrating an exemplary system for magnetic resonance imaging according to some embodiments of the present disclosure. As shown in FIG. 3C, the system 300 may include an MR scanner 310, an RF receiving coil 320, and a transmission component 330. More descriptions for the MR scanner 310 and the RF receiving coil 320 may be found elsewhere in the present disclosure. See, for example, FIGS. 1 and 2 and the descriptions thereof.

The transmission component 330 may include a first pulley 331, a second pulley 334, and a first cable 332. The first pulley 331 may be connected with the RF receiving coil 320 via a connecting part 340. The second pulley 334 may be arranged on the MR scanner 310, and a first end of the first cable 332 may be connected with the first pulley 331. A second end of the first cable 332 may extend outside of the MR scanner 310 after bypassing the first pulley 331. In some embodiments, the first pulley 331 may slide onto the first cable 332.

The second pulley 334 may reverse a direction of the first cable 332. By controlling the second end of the first cable 332, it is possible to adjust a tightness of the first cable 332 while controlling the horizontal movement of the RF receiving coil 320 on the first cable 332 based on the first pulley 331, thereby controlling a depth position of the RF receiving coil 320 within the MR scanner 310. By controlling the second end of the first cable 332, the length of the first cable 332 in the internal cavity of the MR scanner 310 may be controlled. As the first end of the first cable 332 is fixed, the tension of the first cable 332 in the internal cavity of the MR scanner 310 may be adjusted. By adjusting the tightness of the first cable 332, combined with the gravity of the first pulley 331 and the gravity of the RF receiving coil 320, the vertical movement of the RF receiving coil 320 may be controlled, thereby controlling a height position of the RF receiving coil 320 within the MR scanner 310. For example, when the second end of the first cable 332 is pulled and the first cable 332 is tensioned, the first pulley 331 may move towards the direction close to the second pulley 334 on the first cable 332, thereby achieving horizontal movement of the RF receiving coil 320. Meanwhile, when the first cable 332 is tightened, the degree of downward bending of the first cable 332 may decrease, and the first pulley 331 and the RF receiving coil 320 may move vertically upwards until the first cable 332 is tightened to a situation that the first end is close to horizontal with the first pulley 331. When loosening the first cable 332, under the action of the gravity of the first cable 332, the gravity of the first pulley 331, and the gravity of the RF receiving coil 320, the first cable 332 may droop and bend downwards, and the RF receiving coil 320 may move vertically downwards.

Meanwhile, due to the bending of the first cable 332, the first pulley 331 may slide towards the lowest point of the first cable 332 (e.g., a midpoint of a portion of the first cable 332 in the internal cavity of the MR scanner 310), thereby achieving horizontal movement of the RF receiving coil 320.

In some embodiments, the transmission component 330 may also include a driving element 350 and a direction change assembly (e.g., the first direction change assembly 360 and the second direction change assembly 370). More descriptions on the driving element 350 and the direction change assembly may be found in FIG. 3B and the relevant descriptions.

FIG. 3D is a schematic diagram illustrating another exemplary system for magnetic resonance imaging according to some embodiments of the present disclosure. As shown in FIG. 3D, the system 300 may include a MR scanner 310, an RF receiving coil 320, and a transmission component 330. More descriptions for the MR scanner 310 and the RF receiving coil 320 may be found elsewhere in the present disclosure. See, for example, FIGS. 1 and 2 and the descriptions thereof. In some embodiments, the transmission component 330 may include a first pulley 331, a first cable 332, a second cable 333, and a second pulley 334. For more information on the first pulley 331, first cable 332, and second pulley 334, which may refer to FIG. 3C and the relevant descriptions. More descriptions on the second cable 333 may be found elsewhere in the present disclosure, for example, FIG. 3B and the relevant descriptions. In some embodiments, in order to improve the accuracy of the horizontal movement of the RF receiving coil 320, a second cable 333 and a second pulley 334 may be simultaneously provided, and the horizontal movement of the RF receiving coil 320 may be controlled jointly by the second cable 333 and the first cable 332.

As shown in FIG. 3C, in some embodiments, the transmission component 300 may also include a second cable 333. A first end of the second cable 333 may be connected with the RF receiving coil 320, and a second end of the second cable 333 may extend outside of the MR scanner 310. The arrangement of the second cable 333 may further control the RF receiving coil 320, thus improving the accuracy for controlling the RF receiving coil 320 to move and reducing the difficulty for controlling the RF receiving coil 320 to move.

As the second cable 333 is connected with the RF receiving coil 320, the RF receiving coil 320 may be moved from the left side of the MR scanner 310 to the right side of the MR scanner 310 by drawing the second end of the second cable 333 and releasing the second end of the first cable 332. At the same time, the first cable 332 and the second cable 333 may apply two forces with different directions on the RF receiving coil 320, thereby controlling the deployment of the RF receiving coil 320. Furthermore, by controlling the tightness of the first cable 332 and the second cable 333, it is possible to control the vertical movement of the RF receiving coil 320. Specifically, by controlling the second cable 333 to be driven, the influence of the second cable 333 on the RF receiving coil 320 may avoided. By controlling the tension or relaxation of the first cable 332, combined with the gravity of the first pulley 331 and the RF receiving coil 320, the vertical movement of the RF receiving coil 320 may be achieved, the more description may refer to FIG. 3C and the relevant descriptions. It should be noted that in the present disclosure, the meaning of “driven to move” refers to not actively applying a power source, but moving with a movement of a relevant subject. For example, drawing the first cable 332, and the second cable 333 may be driven to move, thus when controlling the RF receiving coil 320 to move towards left, only force is applied on the first cable 332. The first cable 332 actively moves based on the applied force, thereby driving the RF receiving coil 320 to move, and the second cable 333 may follow a movement of the RF receiving coil 320 to move passively.

In some embodiments, the transmission component 330 may also include a driving element 350 and a direction change assembly (e.g., the first direction change assembly 360 and the second direction change assembly 370). More descriptions on the driving element 350 and the direction change assembly may be found in elsewhere in the present disclosure, for example, FIG. 3B and the relevant descriptions.

The working principle of the system shown in FIG. 3C is described position as follows: when moving a bed position of the plurality of bed positions to allow a subject to enter the MR scanner 310, the RF receiving coil 320 may need to be moved from an intermediate position to a target position. In some embodiments, the intermediate position may be located at an end (e.g., a right end shown in FIG. 3C) of MR scanner 310, and may also be located at a top of an internal cavity of MR scanner 310 to avoid affecting the internal cavity for accommodating the bed position in the MR scanner 310. The target position may be located at the center of the internal cavity of the MR scanner 310 and close to the body surface of the patient to ensure that the RF receiving coil 320 may cover the body surface of a segment of the subject that needs to be examined (e.g., a segment from the brain to the middle thigh of the patient, etc.), thus avoiding situations where a depth of the couch entering the internal cavity of MR scanner 310 is insufficient, resulting in the RF receiving coil 320 not being able to cover the body surface of the patient, or where the depth of the couch entering the internal cavity of MR scanner 310 is too deep, resulting in the RF receiving coil 320 covering the body surface of a segment of the patient that does not need to be examined (e.g., a lower segment of the leg).

By drawing the second end of the first cable 332 (when there is no external force applied on the second end of the second cable 333, and the second cable 333 is driven to move), the RF receiving coil 320 may be controlled to move from the target position at the right side of the MR scanner 310 to the center of the internal cavity of the MR scanner 310 as show in FIG. 3C. Furthermore, by loosening the second end of the first cable 332 and the second end of the second cable 333, the RF receiving coil 320 may be lowered under the action of gravity until the RF receiving coil 320 is close to or in contact with the body surface of the patient and reaches the target position. After the RF receiving coil 320 reaches the target position, the MR scanner 310 may start to scan the subject.

After the scanning is completed, the RF receiving coil 320 may be controlled to rise by drawing the second end of the first cable 332 and the second end of the second cable 333. By drawing the second end of the second cable 333 and loosening the second end of the first cable 332, it is possible to move the RF receiving coil 320 from the left side to the right side of the MR scanner 310 as shown in FIG. 3C until the RF receiving coil 320 moves to the intermediate position. After the RF receiving coil 320 is moved to the intermediate position, the bed position may be moved to switch patients within the MR scanner 310 for the next scanning.

In some embodiments, by controlling the tightness of the first cable 332 and the second cable 333, the vertical movement of the RF receiving coil 320 may be indirectly controlled, but there may be a problem of insufficient control accuracy, and an additional horizontal movement of the RF receiving coil 320 may also exist, thus affecting a positioning of the RF receiving coil 320. In some embodiments, a third cable (e.g., the third cable 335 in FIG. 3E) may be installed to directly control the vertical movement of the RF receiving coil 320 based on the third cable, achieving the goal of improving the control accuracy.

FIG. 3E is a schematic diagram illustrating another exemplary system for magnetic resonance imaging according to some embodiments of the present disclosure. As shown in FIG. 3E, the system 300 may include an MR scanner 310, an RF receiving coil 320, and a transmission component 330. More descriptions for the MR scanner 310 and the RF receiving coil 320 may be found elsewhere in the present disclosure. See, for example, FIGS. 1 and 2 and the descriptions thereof. In some embodiments, the transmission component 330 may include a first pulley 331, a first cable 332, a second cable 333, a second pulley 334, and a third cable 335. More descriptions of the first pulley 331, the first cable 332, the second cable 333, and the second pulley 334 may be found elsewhere in the present disclosure, for example, FIG. 3D and the relevant descriptions. A first end of the third cable 335 may be connected with the RF receiving coil 320, and a second end of the third cable 335 may be connected with the MR scanner 310 after bypassing the first pulley 331. A distance between the RF receiving coil 320 and the second end of the third cable 335 may be adjusted based on the third cable 335, thereby controlling the movement of the RF receiving coil 320.

In some embodiments, a connection position between the second end of the third cable 335 and the MR scanner 310 may be located directly above the target position, allowing the third cable 335 to accurately control the vertical movement of the RF receiving coil 320.

Specifically, when the RF receiving coil 320 is controlled to move to a position corresponding to the target position (i.e., a position directly above the target position) by the first cable 332 and the second cable 333, the first cable 332 and the second cable 333 may be loosened, and the third cable 335 may be pulled to drive the first pulley 331 and the RF receiving coil 320 to rise vertically. Alternatively, by loosening the first cable 332, the second cable 333, and the third cable 335, the RF receiving coil 320 may descend vertically under the action of gravity.

In some embodiments, the second end of the third cable 335 may be connected with the MR scanner 310 based on a fixing part 380. The arrangement of the fixing part 380 may enhance the stability of the connection between the second end of the third cable 335 and the MR scanner 310. The position of the fixing part 380 may be the connection position between the second end of the third cable 335 and the MR scanner 310. Therefore, the fixing part 380 may be located at the top of an internal cavity of the MR scanner 310 directly above the target position.

In some embodiments, the transmission component 330 may also include a driving element 350 and a direction change assembly (e.g., the first direction change assembly 360 and the second direction change assembly 370). More description of the driving element 350 and the direction change assembly may be found elsewhere in the present disclosure, for example, FIG. 3B and the relevant descriptions.

In some embodiments, the transmission component (e.g., the transmission component 430 in FIGS. 4-6) may also provide at least two movement freedoms for the RF receiving coil (e.g., the RF receiving coil 420 in FIGS. 4-6) via applying deformation forces in at least two directions to the RF receiving coil. Compared to a tension (a drawing force) provided by the cable, the deformation force may be more stable, and the control of the RF receiving coil may be more accurate.

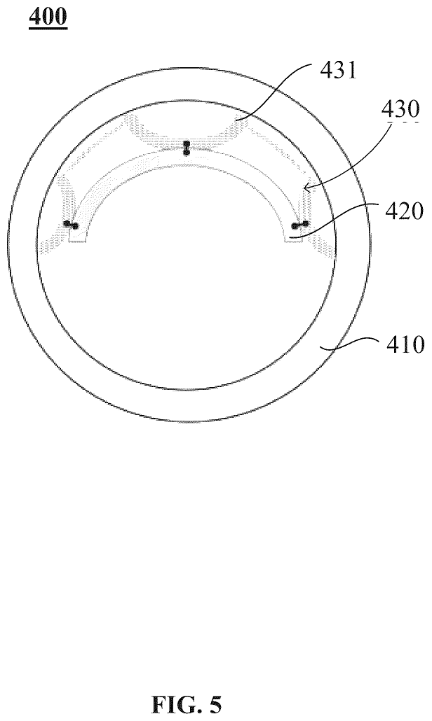

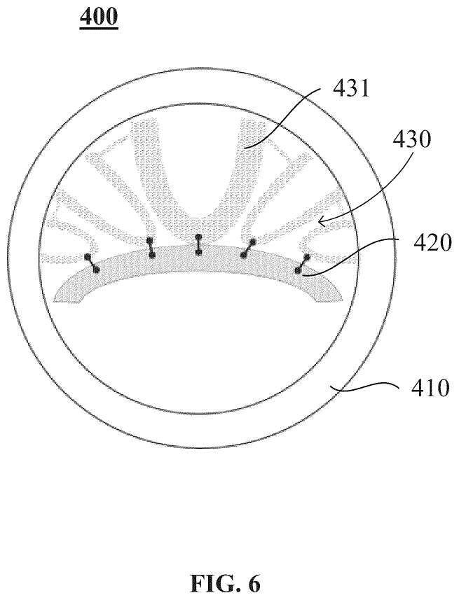

FIG. 4 is a schematic diagram illustrating an exemplary gas bag of a system for magnetic resonance imaging when the gas bag is expanding according to some embodiments of the present disclosure. FIG. 5 is a schematic diagram illustrating an exemplary gas bag of a system for magnetic resonance imaging when the gas bag is contracting according to some embodiments of the present disclosure. FIG. 6 is another schematic diagram illustrating an exemplary system for magnetic resonance imaging according to some embodiments of the present disclosure. As shown in FIGS. 4-6, the system 400 may include an MR scanner 410, an RF receiving coil 420, and a transmission component 430. More descriptions for the MR scanner 410 and the RF receiving coil 420 may be found elsewhere in the present disclosure. See, for example, FIGS. 1 and 2 and the descriptions thereof.

The transmission component 430 may include one or more gas bags 431. One of the sides of each of the one or more gas bags 431 may be connected with the MR scanner 410, and one of the sides of each of the one or more gas bags 431 may be connected with the RF receiving coil 420. By controlling the expansion or contraction of one or more gas bags 431 and applying deformation forces in at least two directions to the RF receiving coil 420, the RF receiving coil 420 may be driven to move, thereby adjusting the position of the RF receiving coil 420.

In some embodiments, one of the one or more gas bags 431 may be an arched gas bag to provide good support performance. In some embodiments, one or more gas bags 431 may located at the top of the internal cavity of the MR scanner 410. When a subject needs to be scanned, the one or more gas bags 431 may be controlled to expand to drive the RF receiving coil 420 to move downwards, causing the RF receiving coil 420 to move to a target position close to the body surface of the patient, and keeping the RF receiving coil 420 at the target position during the scanning process. After the scan is completed, the one or more gas bags 431 may be controlled to contract to drive the RF receiving coil 420 to move upwards, causing the RF receiving coil 420 to move to the intermediate position above the target position to avoid interference with the movement of the bed position and the patient. The intermediate position may be located above the target position and near the top of the internal cavity of the MR scanner 410.

In some embodiments, a count of the one or more gas bags 431 may be three, and the three gas bags 431 may be symmetrically distributed. An axis of symmetry of the three gas bags 431 may be a vertical centerline of the internal cavity of MR scanner 410 as shown in FIGS. 4-5. The one or more symmetrically distributed gas bags 431 may apply more uniform force to the RF receiving coil 420, which may be beneficial for unfolding the RF receiving coil 420. In some embodiments, the volume of a gas bag 431 located in a middle position may be greater than volumes of gas bags 431 located on both sides, to control a bending degree of the RF receiving coil 420. In some embodiments, the transmission component 430 may also include a driving element (not shown), which may simultaneously control the expansion and contraction of the one or more gas bags 431. In some embodiments, the driving element may include one or more driving sources, and each of one or more driving sources may be connected to a gas bag 431. In some embodiments, one of the one or more driving sources may be an inflation and deflation type mechanism. For example, the driving source may be a blower, which may be configured to inflate the gas bag 431 and maintain an inflation state, or may deflate the gas bag 431, causing the gas bag 431 to contract. In some embodiments, the driving element may be located outside the MR scanner 410, and the one or more driving sources of the driving element may be connected to the corresponding one or more gas bags 431 via a pipeline to improve the flexibility for arranging the driving element.

In some embodiments, the count of the one or more gas bags 431 may also be 5 (as shown in FIG. 6) or other counts. The one or more gas bags 431 may be symmetrically distributed, and volumes of one or more gas bags 431 located near an axis of symmetry may be greater than volumes of one or more gas bags 431 at both ends far from the axis of symmetry.

Some embodiments of the present disclosure may also provide a system. The system may include at least one storage medium including a set of instructions; and at least one processor in communication with the at least one storage medium. When at least one processor executes the set of instructions, at least one processor may be directed to cause the system to perform operations. In some embodiments, the operation may include: (1) after a couch moves for a scan of a first bed position among a plurality of bed positions, moving the RF receiving coil to a target position; (2) after an MR scanner performs the scan of the first bed position when the RF receiving coil is at the target position, moving the RF receiving coil from the target position to an intermediate position; (3) and after the couch moves for a scan of a second bed position among the plurality of bed positions, moving the RF receiving coil from the intermediate position to the target position.

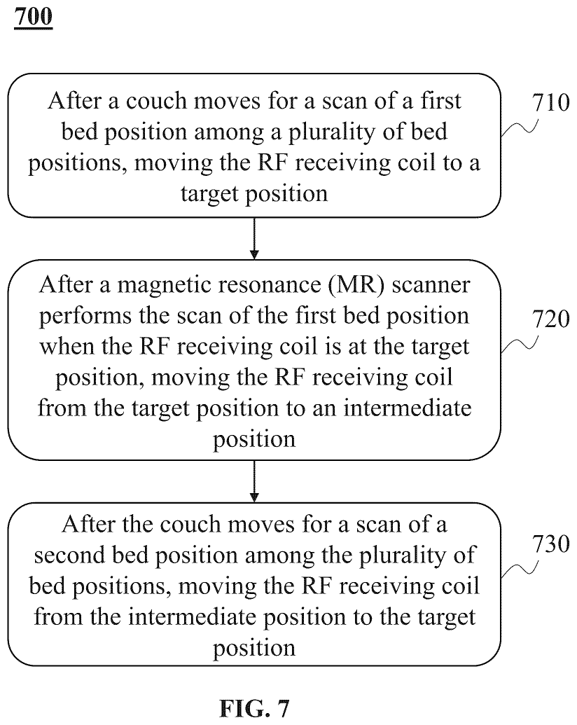

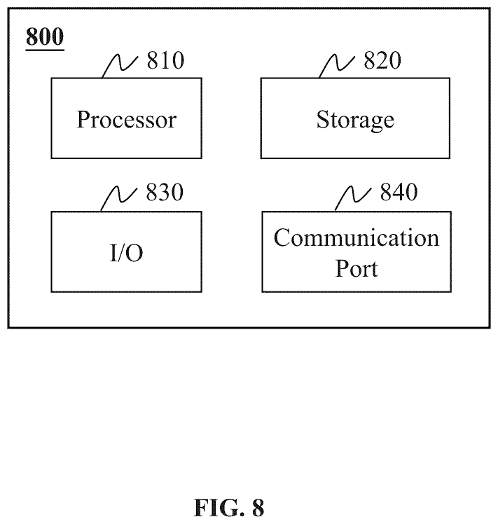

FIG. 7 is a flowchart illustrating an exemplary process of MR scanning according to some embodiments of the present disclosure. As shown in FIG. 7, process 700 may include the following operations. In some embodiments, process 700 may be performed by one or more components of the system 100. For example, process 700 may be performed by the processing device 120 and/or the medical device 110. In some embodiments, process 700 may be performed by the system 800 shown in FIG. 8.

In 710, after a couch moves for a scan of a first bed position among a plurality of bed positions, an RF receiving coil may be moved to a target position.

In some embodiments, a subject on the couch may be a human, an animal, or a portion thereof, including, for example, an organ, a texture, a region, an object, a lesion, a tumor, etc., or any combination thereof. For example, the subject may include the head, a breast, a lung, the trachea, the pleura, the mediastinum, the abdomen, a long intestine, the small intestine, the bladder, the gallbladder, the triple focus, the pelvic cavity, the spine, a limb, the skeleton, a blood vessel, etc., or any combination thereof. In some embodiments, the subject may be the body of a patient. In some embodiments, during the scanning process, the couch may be located at a plurality of bed positions. By moving the couch to different bed positions, the MR scanner may scan different areas of the subject on the couch. For example, a first area (such as the chest) of the subject may be scanned at the first bed position, etc.

In some embodiments, changes between different bed positions may be achieved through the movement of an MR scanner. The target position refers to the position of the RF receiving coil for receiving MR signals during the scanning process. After the couch is moved to the first bed position, the RF receiving coil may be moved to the target position for receiving MR signals generated during the scan of the first bed position of the subject, so that the RF receiving coil may be close to the first area of the patient, and a scan of the first bed position may begin.

In some embodiments, the RF receiving coil may be moved to the target position by a transmission component as described elsewhere in the present disclosure. For example, the transmission component may be controlled by the processing device 120 to drive the RF receiving coil to move to the target position. As a further example, the processing device 120 may control the transmission component to drive the RF receiving coil to move to the target position according to an instruction input by an operator. More descriptions of the MR scanner, the RF receiving coil, and the target position may be found elsewhere in the present disclosure, for example, FIG. 1 and FIG. 2, and the relevant descriptions.

In 720, after an MR scanner performs the scan of the first bed position when the RF receiving coil is at the target position, the RF receiving coil may be moved from the target position to an intermediate position.

In some embodiments, during the process of performing the scan of the first bed position by the MR scanner, the RF receiving coil may remain at the target position by the transmission component. After the MR scanner finishes the scan of the first bed position, the RF receiving coil may move from the target position to the intermediate position. The intermediate position may be any position that does not affect the movement of the couch. The movement of the RF receiving coil may be achieved through the transmission component. More descriptions about the intermediate position may be found elsewhere in the present disclosure, for example, FIG. 1 and FIG. 2, and the relevant descriptions. More descriptions about the transmission component may be found elsewhere in the present disclosure, for example, FIGS. 3A-6, and the relevant descriptions. For example, the RF receiving coil may be moved to the intermediate position by a transmission component as described elsewhere in the present disclosure. For example, the transmission component may be controlled by the processing device 120 to drive the RF receiving coil to move to the intermediate position.

In 730, after the couch moves for a scan of a second bed position among the plurality of bed positions, the RF receiving coil may be moved from the intermediate position to the target position.

A second area (e.g., the abdomen) that is different from the first area of the subject may be scanned at the second bed position that is different from the first bed position. After the couch is moved to the second bed position, the RF receiving coil may be moved from the intermediate position to the target position, so that the RF receiving coil may be close to the second area of the subject, thereby performing the scan of the second bed position.

In some embodiments, during the couch moves from the first bed position to the second bed position, the RF receiving coil may be moved from the intermediate position to the target position. For example, when the couch starts to move from the first bed position to the second bed position, the couch moves from the first bed position to the second bed position.

In some embodiments, when the couch is moved to the plurality of bed positions for scanning, the operations 710, 720, and 730 may be repeated to performing the scan of each the plurality bed positions, separately.

FIG. 8 is a block diagram illustrating an exemplary system for magnetic resonance imaging according to some embodiments of the present disclosure. In some embodiments, one or more components of the system 300 or the system 400 may be implemented on one or more components of the system 800. Merely by way of example, the processing device 120 and/or the terminal 140 may be implemented on one or more components of the system 800, respectively. As shown in FIG. 8, the system 800 may include at least one processor 810 and at least one storage 820. The at least one storage 820 may store a set of instructions, and the at least one processor 810 may communicate with at least one storage 820 to execute the set of instructions. The set of instructions may include, for example, programs, objects, components, data structures, processes, modules, and functions, which may perform specific functions described in the present disclosure (e.g., the process 700).

In some embodiments, the storage 820 may store data/information obtained from the medical device 110, the storage device 130, the terminal 140, and/or any other components of system 100. In some embodiments, the storage 820 may include mass storage devices, removable storage devices, volatile read-write memory, read-only memory (ROM), or the like, or a combination thereof. For example, mass storage devices may include a disk, an optical disk, a solid-state drive, or the like. The removable storage devices may include a flash drive, a floppy disk, an optical disk, a storage card, a compressed disk, a magnetic tape, etc. The volatile read-write memory may include a random-access memory (RAM). The RAM may include dynamic RAM (DRAM), dual data rate synchronous dynamic RAM (DDR-SDRAM), static RAM (SRAM), thyristor RAM (T-RAM), and zero capacitance RAM (Z-RAM). The ROM may include a mask ROM (MROM), a programmable ROM (PROM), a erasable programmable ROM (EPROM), an electrically erasable programmable ROM (EEPROM), a compact disc ROM (CD-ROM), and a digital multifunctional disk ROM. In some embodiments, the storage 820 may store one or more programs and/or instructions to execute the exemplary methods described in the present disclosure (e.g., the process 700).

In some embodiments, when executing the set of instructions, the processor 810 may be configured to cause the system 800 to perform at least the following operations: after a couch moves for a scan of a first bed position among a plurality of bed positions, moving the RF receiving coil to a target position; after an MR scanner performs the scan of the first bed position when the RF receiving coil is at the target position, moving the RF receiving coil from the target position to an intermediate position; after the couch moves for a scan of a second bed position among the plurality of bed positions, moving the RF receiving coil from the intermediate position to the target position. More descriptions on the processor 810 may refer to the processing device 120 in FIG.1 and the relevant descriptions.

Merely by way of example, only one processor is described in the system 800. However, it should be noted that the system 800 in the present disclosure may also include multiple processors. Therefore, the operations and/or method steps executed by one processor as described in the present disclosure may also be jointly or separately executed by the multiple processors. For example, the processor of the system 800 executes operations A and B simultaneously, it should be understood that operations A and B may also be executed jointly or separately by two or more different processors in system 800 (e.g., a first processor executes operation A, a second processor executes operation B, or the first processor and the second processor jointly execute operations A and B).

In some embodiments, the system 800 may also include an input/output (I/O) 830. The I/O 830 may input and/or output signals, data, information, etc. In some embodiments, the I/O 830 may allow a user interaction with the system 800 (e.g., the processor 810). In some embodiments, the I/O 830 may include an input device and an output device. The input device may include a keyboard, a mouse, a touch screen, a microphone, or the like, or any combination thereof. The output device may include a display device, a speaker, a printer, a projector, or the like, or any combination thereof. The display device may include a liquid crystal display (LCD), a light-emitting diode (LED) based display, a flat panel display, a curved screen, a television device, a cathode ray tube (CRT), a touch screen, or the like, or any combinations thereof.

In some embodiments, the system 800 may also include a communication port 840. The communication port 840 may be connected to a network (e.g., the network 150 in FIG. 1) to facilitate data communication. The communication port 840 may establish a connection between the system 800 (e.g., the processor 810) and one or more components of the system 100 (e.g., the medical device 110, the storage device 130, and/or the terminal 140). The connection may be a wired connection, a wireless connection, or the like, or any other communication connection that enables data transmission and/or reception, and/or a combination thereof. The wired connection may include, for example, cables, optical cables, telephone lines, or any combination thereof. The wireless connection may include, for example, a Bluetooth™ connection, a Wi-Fi™ link, a WiMax™ link, a WLAN link, a PurpleBee™ link, a mobile network link (e.g., a 3G, a 4G, a 5G, etc.), or any combination thereof. In some embodiments, the communication port 840 may be or may include a standardized communication port, such as RS232, RS485, etc. In some embodiments, the communication port 840 may be specially designed. For example, the communication port 840 may be designed based on a digital imaging and medical communication (DICOM) protocol.

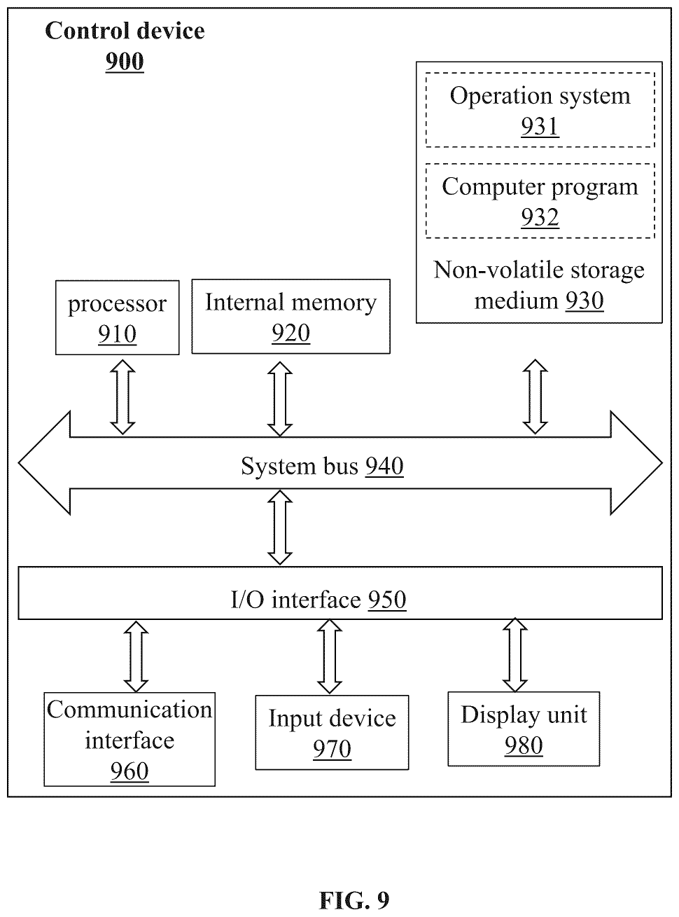

FIG. 9 is a schematic diagram illustrating an exemplary control device of a system for magnetic resonance imaging according to some embodiments of the present disclosure. In some embodiments, the system 100 may include a control device 900. In some embodiments, the one or more components of the system 300 or the system 400 may be implemented on the control device. Merely by way of example, the processing device 120 and/or the terminal 140 may be implemented on the control device 900.

As shown in FIG. 9, the control device 900 may include a processor 910 connected through a system bus 940, a memory (including internal memory 920 and a non-volatile storage medium 930), a communication interface 960, an input device 970 and a display unit 980. The communication interface 960, the input device 970, and the display unit 980 may be connected to the system bus 940 through the I/O interface 950.

The processor 910 may be configured to provide computing and control capabilities. In some embodiments, the processor 910 may perform the feedback mode of the navigation operation as described in some embodiments of the present disclosure by executing computer instructions (e.g., a computer program 932) in the memory. The non-volatile storage medium 930 may store an operation system 931 and a computer program 932. The internal memory 920 may provide an operation environment for the operation system 931 and the computer program 932 in the non-volatile storage medium 930.

The communication interface 960 may be configured for wired or wireless communication with an external terminal (e.g., the terminal 140, the medical device 110, and the storage device 130). The display unit 980 may be configured to display various types of information such as an interactive interface with a user. The display unit 980 may include various types of display screens, for example, a liquid crystal display screen, an e-ink display screen, a VR display device, etc. The input device 970 may be configured for user input and may include various input devices, for example, keys integrated into the device itself, a trackball or a touchpad, etc., a touch layer covered on the touch screen, an external keyboard, a touchpad or a mouse, etc.

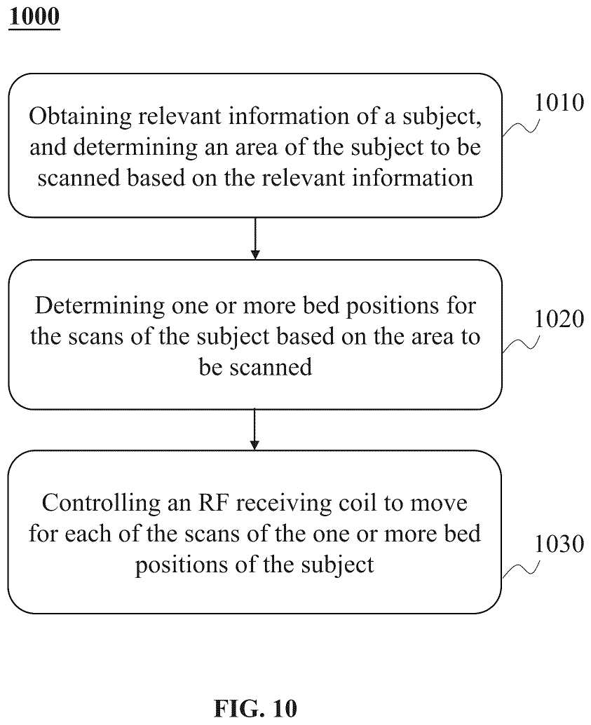

FIG. 10 is a flowchart illustrating an exemplary process of scanning performed by a medical device according to some embodiments of the present disclosure. As shown in FIG. 10, process 1000 may include the following operations. In some embodiments, process 1000 may be performed by one or more components of the system 100. For example, process 1000 may be performed by the processing device 120 and/or the medical device 110.

In 1010, relevant information of a subject may be obtained, and an area of the subject to be scanned may be determined based on the relevant information.

In some embodiments, the relevant information may include dimensional data of the subject (e.g. patient's height, etc.), historical data of the subject (e.g. the patient's medical history, etc.), an operating standard (e.g., a scanning protocol, a scanning mode, etc.), etc. In some embodiments, the relevant information may be obtained by the processing device 120, and may be stored in the storage device 130, or may be input through the terminal 140.

In some embodiments, the subject may be the body of a human. More descriptions about the subject may be found elsewhere in the present disclosure.

In some embodiments, the area to be scanned may include one of different areas of the human's body (such as the chest, etc.). In some embodiments, based on the relevant information, the location of the body's lesion may be determined, and the area to be scanned may be an area including the lesion.

In some embodiments, the size of the area to be scanned may be related to the height of the body and the specification of the MR scanner. The specification of the MR scanner may refer to the axis field of view of the MR scanner. For example, the length (i.e., the height) of the body is 1910 mm and the axial field of view of the MR scanner is 320 mm. When the area to be scanned is from the human's skull top to the mid-thigh, the range of the area to be scanned may be “ human's height*0.54+95 mm”. When the area to be scanned is from the human's skull base to the mid-thigh, the range of the area to be scanned may be “ human's height*0.54+214 mm”. When the area to be scanned is from the human's skull top to the toes, the range of the area to be scanned may be “ human's height+194 mm”.

In 1020, one or more bed positions for the scans of the subject may be determined based on the area to be scanned.

In some embodiments, the area to be scanned may correspond to one or more different bed positions. For example, when the area to be scanned is from the human's skull top to the mid-thigh, the corresponding bed positions may include a first bed position, a second bed position, and a third bed position. As another example, when the area to be scanned is from the human's skull base to the mid-thigh, the corresponding bed positions may include the second bed position and the third bed position. As still another example, when the area to be scanned is from the human's skull top to the toes, the corresponding bed positions may include the first bed position, the second bed position, the third bed position, a fourth bed position, a fifth bed position, and a sixth bed position. As a further example, the human's is 1910 mm and the axial field of view of the MR scanner is 320 mm, and the human's body enters the scanning region of the MR scanner from the head to the toes. Using the maintenance end of the MR scanner as a reference, the first bed position may be 640 mm-800 mm from the maintenance end of the MR scanner, the second bed position may be 800 mm-1040 mm from the maintenance end of the MR scanner, the third bed position may be 960 mm-1280 mm from the maintenance end of the MR scanner, the fourth bed position may be 1120 mm-1520 mm from the maintenance end of the MR scanner, the fifth bed position may be 1280 mm-1760 mm from the maintenance end of the MR scanner, and the sixth bed position may be 1440 mm-2000 mm from the maintenance end of the MR scanner.

In 1030, an RF receiving coil may be controlled to move for each of the scans of the one or more bed positions of the subject .

In some embodiments, the scans of the subject corresponding to the one or more bed positions may be performed by an MR scanner in sequence. In some embodiments, when the one or more bed positions includes multiple bed positions, the movement of the RF receiving coil for the multiple bed positions may be controlled according to process 700. For example, the couch placing the subject may be moved at the first bed position and the RF receiving coil may be moved to a target position for performing the scan of the first bed position. After an MR scanner performs the scan of the first bed position when the RF receiving coil is at the target position, the RF receiving coil may be moved away from the target position to an intermediate position and the couch may be moved to the second bed position. After the couch arrives at the second bed position among the plurality of bed positions, the RF receiving coil may be moved from the intermediate position to the target position and the scan of the second bed position may be performed by the MR scanner. The movement of the RF receiving coil during the other bed positions in the plurality of bed positions may be controlled similarly as the movement of the first bed position and the second bed position. In some embodiments, for different bed positions, the target position of the RF receiving coil may be different or the same. In some embodiments, for different bed positions, the intermediate position may be the same or different. In some embodiments, during the RF receiving coil moves from the target position to the intermediate position for the scan of the next bed position, the couch may be controlled to move from the current bed position to the next bed position. In some embodiments, during the RF receiving coil moves from the intermediate position to the target position for the scan of the next bed position, the couch may be controlled to move from the current bed position to the next bed position. In some embodiments, after the scan of the current bed position is completed, the RF receiving coil may be controlled to move from the target position to the intermediate position for the scan of the next bed position, and after the RF receiving coil arrives at the intermediate position, the couch may be controlled to move from the current bed position to the next bed position and after the couch arrives at the next bed position, the RF receiving coil may be controlled to move from the intermediate position to the target position for the scan of the next bed position.

In some embodiments, after completing the scan of at least one bed position, the processing device may further determine whether a partial scan is needed based on the scan results of the scans of the one or more bed positions. If each of the scan results satisfies a condition (for example, the lesion is clear), the MR scanning may end. If one of the scan results does not satisfy a condition (for example, the lesion is blurred), a partial scan corresponding to a bed position whose scan result does not satisfy the condition may be performed again. In some embodiments, the scan result may include an MR image. Determining whether the scan result satisfies the condition may include determining whether a quality of the MR image satisfies the condition. The quality of the MR image may be associated with one or more evaluation factors, such as a signal to noise ratio (SNR), a contrast, a resolution, a definition, etc. For example, the quality of the MR image may be defined by a quality score or a quality level that is determined based on the one or more evaluation factors. As a further example, the quality of the MR image may be defined by a quality score or a quality level that is determined using a trained machine learning model. The MR image and/or the one or more evaluation factors of the MR image may be inputted into the trained machine learning model and the quality (e.g., the quality score or a quality level) of the MR image may be outputted by the trained machine learning model.

Integrated positron emission tomography/magnetic resonance (PET/MR) as a simulator for radiation therapy (RT) is technically challenging. Unlike PET/MR images used for diagnosis, images used for radiotherapy planning need to be collected in the radiotherapy position to better align with CT simulation positioning images, accurately delineate the target area, and formulate radiotherapy plans.

In some embodiments, a flat couch for PET/MR-Sim and position fixing component the same with CT-sim may be used to get a better repetition of the radiotherapy position, so as the use of 3D laser position system. The implement of the flat couch improves the repeated position accuracy. In some embodiments, the deformation of the flat couch is less than 1 mm at 150 kg load. In some embodiments, the RF receiver coil of MR may be set to reduce contact with the subject's body surface to prevent external contour deformation and organ displacement caused by physical compression. Hence, a specialized head coil for RT planning may be used for the imaging acquisition. In some embodiments, the attenuation correction of the head coil and position fixing hardware may also be corrected to achieve accurate quantitative PET imaging.

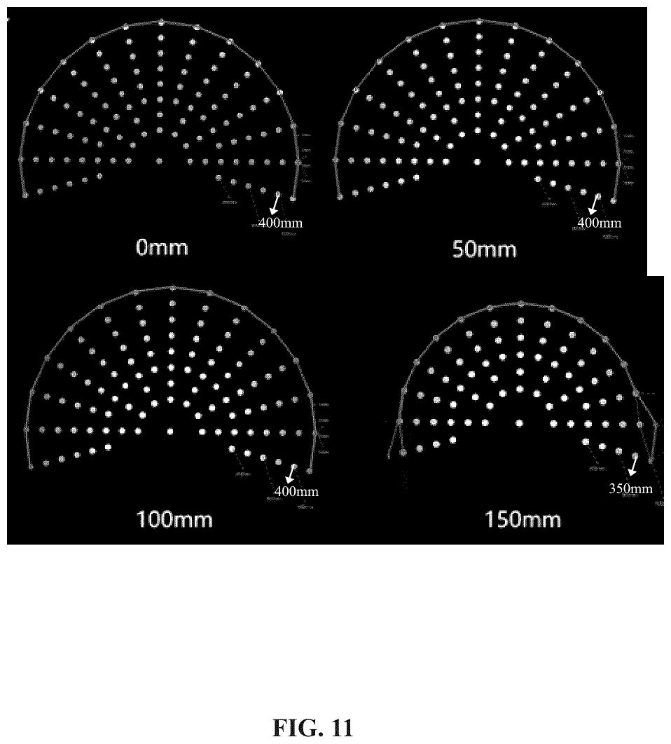

FIG. 11 is QA results for geometric distortion after the gradient linearity calibration. To reduce the geometric distortion to the RT standard, a phantom with a diameter of 320 mm may be used to perform precise gradient linearity calibration. And a slice phantom may be used in the quality assurance (QA) of the distortion. As shown in FIG. 11, the 1 mm distortion contour lines are always located outside the marker point with a diameter of 400 mm, when z=0 mm, 50 mm and 100 mm. When z=150 mm, the 1 mm distortion contour line converges toward the inner circle with a diameter of 350 mm. These results indicate that the geometric distortion which is less than 1 mm is achieved within a DSV of 400 mm.

Having thus described the basic concepts, it may be rather apparent to those skilled in the art after reading this detailed disclosure that the foregoing detailed disclosure is intended to be presented by way of example only and is not limiting. Various alterations, improvements, and modifications may occur and are intended for those skilled in the art, though not expressly stated herein. These alterations, improvements, and modifications are intended to be suggested by this disclosure and are within the spirit and scope of the exemplary embodiments of this disclosure.

Moreover, certain terminology has been used to describe embodiments of the present disclosure. For example, the terms “one embodiment,” “an embodiment,” and/or “some embodiments” mean that a particular feature, structure or characteristic described in connection with the embodiment is included in at least one embodiment of the present disclosure. Therefore, it is emphasized and should be appreciated that two or more references to “an embodiment” or “one embodiment” or “an alternative embodiment” in various portions of the present disclosure are not necessarily all referring to the same embodiment. Furthermore, the particular features, structures or characteristics may be combined as suitable in one or more embodiments of the present disclosure.

Furthermore, it will be appreciated by one skilled in the art, aspects of the present disclosure may be illustrated and described herein in any of a number of patentable classes or context including any new and useful process, machine, manufacture, or composition of matter, or any new and useful improvement thereof. Accordingly, aspects of the present disclosure may be implemented entirely hardware, entirely software (including firmware, resident software, micro-code, etc.) or combining software and hardware implementation that may all generally be referred to herein as a “data block,” “module,” “engine,” “unit,” “component,” or “system.” Furthermore, aspects of the present disclosure may take the form of a computer program product embodied in one or more computer readable media having computer readable program code embodied thereon.

A computer readable signal medium may include a propagated data signal with computer readable program code embodied therein, for example, in baseband or as part of carrier wave. Such a propagated signal may take any of a variety of forms, including electro-magnetic, optical, or the like, or any suitable combination thereof. A computer readable signal medium may be any computer readable medium that is not a computer readable storage medium and that may communicate, propagate, or transport a program for use by or in connection with an instruction execution system, apparatus, or device. Program code embodied on a computer readable signal medium may be transmitted using any appropriate medium, including wireless, wireline, optical fiber cable, RF, or the like, or any suitable combination of the foregoing.

Furthermore, the recited order of processing elements or sequences, or the use of numbers, letters, or other designations therefore, is not intended to limit the claimed processes and methods to any order except as may be specified in the claims. Although the above disclosure discusses through various examples what is currently considered to be a variety of useful embodiments of the disclosure, it is to be understood that such detail is solely for that purpose, and that the appended claims are not limited to the disclosed embodiments, but, on the contrary, are intended to cover modifications and equivalent arrangements that are within the spirit and scope of the disclosed embodiments. For example, although the implementation of various components described above may be embodied in a hardware device, it may also be implemented as a software only solution, for example, an installation on an existing server or mobile device.

Similarly, it should be appreciated that in the foregoing description of embodiments of the present disclosure, various features are sometimes grouped together in a single embodiment, figure, or description thereof for the purpose of streamlining the disclosure aiding in the understanding of one or more of the various inventive embodiments. This method of disclosure, however, is not to be interpreted as reflecting an intention that the claimed subject matter requires more features than are expressly recited in each claim. Rather, inventive embodiments lie in less than all features of a single foregoing disclosed embodiment.

In closing, it is to be understood that the embodiments of the application disclosed herein are illustrative of the principles of the embodiments of the application. Other modifications that may be employed may be within the scope of the application. Thus, by way of example, but not of limitation, alternative configurations of the embodiments of the application may be utilized in accordance with the teachings herein. Accordingly, embodiments of the present application are not limited to that precisely as shown and described.

What is claimed is:

1. A system, comprising:
a magnetic resonance (MR) scanner;
a radio frequency (RF) receiving coil configured to receive an MR signal during each of scans of a plurality of bed positions of a subject; and
a transmission component configured to move the RF receiving coil for each of the scans of the plurality of bed positions of the subject; wherein
the transmission component is configured to apply one or more forces in at least two directions to the RF receiving coil to control the RF receiving coil to move during each of the scans.

2. The system of claim 1, wherein the transmission component is configured to:
after a couch moves for a scan of a first bed position among the plurality of bed positions, move the RF receiving coil to a target position;
after the MR scanner performs the scan of the first bed position when the RF receiving coil is at the target position, move the RF receiving coil from the target position to an intermediate position; and
after the couch moves for a scan of a second bed position among the plurality of bed positions, move the RF receiving coil from the intermediate position to the target position.

3. The system of claim 2, wherein the moving the RF receiving coil from the target position to the intermediate position includes raising the RF receiving coil from the target position to the intermediate position.

4. The system of claim 2, wherein the moving the RF receiving coil from the intermediate position to the target position includes dropping the RF receiving coil from the intermediate position to the target position.

5. The system of claim 2, wherein the transmission component is further configured to keep the RF receiving coil at the target position during the scan of the first bed position or the second bed position.

6. The system of claim 1, wherein the transmission component includes a first pulley connected with the RF receiving coil and a first cable, a first end of the first cable is connected with the MR scanner, and a second end of the first cable extends to outside of the MR scanner after bypassing the first pulley.

7. The system of claim 6, wherein the transmission component includes:
a second cable, a first end of the second cable being connected with the RF receiving coil and a second end of the second cable extending to outside of the MR scanner.

8. The system of claim 1, wherein the transmission component includes:
a first pulley connected with the RF receiving coil;
a second pulley provided on the MR scanner;
a first cable, a first end of the first cable being connected with the first pulley, and a second end of the first cable extending to outside of the MR scanner after bypassing the second pulley.

9. The system of claim 8, wherein the transmission component includes:
a second cable, a first end of the second cable being connected with the RF receiving coil and a second end of the second cable extending to outside of the MR scanner.

10. The system of claim 9, wherein the transmission component includes:
a third cable, a first end of the third cable being connected with the RF receiving coil and a second end of the third cable being connected with the MR scanner after bypassing the first pulley.

11. The system of claim 9, wherein the transmission component includes: one or more pulleys and one or more cables.

12. The system of claim 11, wherein the transmission component further includes: a driving element connected with the one or more cables, the driving element being configured to provide one or more drawings forces to the one or more cables.

13. The system of claim 11, wherein the transmission component further includes: a direction change assembly configured to change a direction of at least one of the one or more cables, the direction change assembly being provided on one end of the MR scanner.

14. The system of claim 1, wherein the transmission component includes one or more gas bags, one of sides of each of the one or more gas bags being connected with the MR scanner, and one of the sides of each of the one or more gas bags being connected with the RF receiving coil.

15. A system, comprising:
at least one storage medium including a set of instructions;
at least one processor in communication with the at least one storage medium, wherein when executing the set of instructions, the at least one processor is directed to cause the system to perform operations including:
after a couch moves for a scan of a first bed position among a plurality of bed positions, moving the RF receiving coil to a target position;
after a magnetic resonance (MR) scanner performs the scan of the first bed position when the RF receiving coil is at the target position, moving the RF receiving coil from the target position to an intermediate position; and
after the couch moves for a scan of a second bed position among the plurality of bed positions, moving the RF receiving coil from the intermediate position to the target position.

16. The system of claim 15, wherein the moving the RF receiving coil from the target position to the intermediate position includes:
raising the RF receiving coil from the target position to the intermediate position.

17. The system of claim 15, wherein the moving the RF receiving coil from the intermediate position to the target position includes:
dropping the RF receiving coil from the intermediate position to the target position.

18. The system of claim 15, wherein the method further includes:
keeping the RF receiving coil at the target position during the scan of the first bed position or the second bed position.

19. A system, comprising:
at least one storage medium including a set of instructions;
at least one processor in communication with the at least one storage medium, wherein when executing the set of instructions, the at least one processor is directed to cause the system to perform operations including:
obtaining relevant information of a subject;
determining, based on the relevant information of the subject, an area of the subject to be scanned;
determining, based on the area of the subject to be scanned, one or more bed positions of a couch for one or more scans of the subject;
controlling movement of an RF receiving coil for each of the one or more scans of the one or more of bed positions of the subject; and
causing a magnetic resonance (MR) scanner to perform the one or more scans of the one or more of bed positions of the subject.

20. The system of claim 19, wherein the controlling movement of an RF receiving coil for each of the one or more scans of the one or more of bed positions of the subject includes:
after a couch moves for a scan of a first bed position among a plurality of bed positions, moving the RF receiving coil to a target position;
after a magnetic resonance (MR) scanner performs the scan of the first bed position when the RF receiving coil is at the target position, moving the RF receiving coil from the target position to an intermediate position; and
after the couch moves for a scan of a second bed position among the plurality of bed positions, moving the RF receiving coil from the intermediate position to the target position.
